(19) United States
(12) Patent Application Publication
(10) Pub. No.: US 2026/0052827 A1
(43) Pub. Date: Feb. 19, 2026

(54) METHOD FOR PREPARING STABLE ORGANIC ELECTROCHEMICAL TRANSISTORS

(71) Applicant: University of Kentucky Research Foundation, Lexington, KY (US)

(72) Inventors: Alexandra Frances Paterson, Lexington, KY (US); Vianna Le, Lexington, KY (US)

(21) Appl. No.: 19/301,481

(22) Filed: Aug. 15, 2025

Related U.S. Application Data
(60) Provisional application No. 63/683,456, filed on Aug. 15, 2024.

(51) Int. Cl. H10K 10/40; B01D 19/00; C08J 3/09; C08J 3/215

(52) U.S. Cl. CPC H10K 10/40; B01D 19/0036; C08J 3/093; C08J 3/215; C08J 2381/00

(57) ABSTRACT

Methods of preparing a polymer solution for organic electrochemical transistor preparation include preparing a solvent solution, preparing a dopant solution, and combining the solvent solution and the dopant solution at 60 to 90 volume percent solvent solution and 10 to 40 volume percent dopant solution. Preparing the solvent solution includes degassing a first solvent to form a degassed first solvent and combining the degassed first solvent with a polymer. Preparing the dopant solution includes degassing a second solvent to form a degassed second solvent and combining the degassed second solvent with a p-dopant.

### CROSS-REFERENCE TO RELATED APPLICATIONS

This application claims priority to U.S. Provisional Application 63/683,456, filed Aug. 15, 2024, which is incorporated by reference herein in its entirety.

### TECHNICAL FIELD

Embodiments of the present disclosure relate to methods of preparing a polymer solution for organic electrochemical transistor preparation and more specifically to methods combining chemical doping with solvent degassing.

### BACKGROUND

Organic mixed ionic-electronic conductors (OMIECs) and organic electrochemical transistors (OECTs), which simultaneously couple and transport ionic and electronic charges, are increasing in prevalence in a variety of applications. For example, OMIECs and OECTs may be utilized in biosensors, medical devices and drug delivery, adaptive healthcare technologies, body-machine interfaces, artificial synapses for coupling neurons and controlling prosthetic devices, neuromorphic hardware and computing, chemical sensing, and agriculture applications, amongst others diverse fields. OECT development has made significant progress but efforts to achieve high on-off current ratios (I_{ON/OFF}) and tuneable threshold voltages (V_{T}) remain as challenges for realizing more complex bioelectronic circuitry. Poor operational stability is also a major concern for OECTs. While stability is a universal requirement for all transistors, OECTs have a unique challenge in that they must be stable while operating in air and a water-based electrolyte simultaneously.

Improving OECT stability in air and water has proven complex. Oxygen (O₂) plays a detrimental role in OECT stability, and O₂ is abundantly present in OECTs that operate in air and water. The redox potential of O₂ is close to redox active OMIEC oxidation potentials and, depending on the quantity of dissolved O₂, the OMIEC and the voltage applied, O₂ can lead to parasitic side reactions that form hydrogen peroxide (H₂O₂) or hydroxide (OH⁻)—both of which have been shown to reduce operational stability in OECTs. Redox reactions between O₂ dissolved in the electrolyte, the atmosphere, and the host OMIEC increase the pH and presence of OH⁻, causing degradation, and lower performance in Poly(3,4-ethylenedioxythiophene):Poly(3,4-ethylenedioxythiophene) polystyrene sulfonate (PEDOT:PSS) OECTs. Additionally, Faradaic reactions with O₂ can corrode the host OMIEC, cause detrimental reactions for biosensors such as lipid peroxidation, oxygen reduction reaction (ORR) side reaction products such as H₂O₂ and OH⁻ impact sensing efficiency and can be toxic to biological environments.

While O₂ and its subsequently generated reaction compounds curtail OMIEC and OECT stability, there is a belief that O₂ can behave as a p-dopant to enhance performance in low ionization energy (IE) organic electronic materials. However, as previously noted O₂ also jeopardizes OECT stability.

### SUMMARY

As such, there is a desire and ongoing need to dope OECTs with a p-dopant without relying on O₂ and its undesirable effect on the stability of OECTs. The present disclosure introduces methods of preparing a polymer solution for organic electrochemical transistor preparation to achieve organic electrochemical transistors with improved stability and performance. Specifically, a two-step materials engineering strategy is leveraged. First, solvents are degassed using a freeze-pump-thaw method, for example. Second, a chemical dopant is introduced into the OMIEC. This two-step strategy simultaneously tunes V_{T}, improves I_{ON/OFF}, and enhances the μC* product, while realizing OECTs with improved stability, and increased I_{ON/OFF} ratios. The two-step technique is shown to be effective for different polymers, solvent and dopants. Accordingly, the methods of the present disclosure utilizing chemical doping with degassed solvents provide a highly effective, low-cost, easy to implement technique that broadly impacts criteria needed to realize more complex OMIEC, OECT, and organic bioelectronic circuitry.

Embodiments of the present disclosure relate to methods of preparing a polymer solution for organic electrochemical transistor preparation. The method includes preparing a solvent solution; preparing a dopant solution; and combining the solvent solution and the dopant solution at 60 to 90 volume percent polymer solvent solution and 40 to 10 volume percent dopant solution. Further, preparing the solvent solution comprises degassing a first solvent to form a degassed first solvent and combining the degassed first solvent with a polymer. Additionally, preparing the dopant solution comprises degassing a second solvent to form a degassed second solvent and combining the degassed second solvent with a p-dopant.

Embodiments of the present disclosure further relate to a polymer solution for organic electrochemical transistor preparation. The polymer solutions comprises a solvent solution comprising a degassed first solvent and a polymer; and a dopant solution comprising a degassed second solvent and a p-dopant. Further, the solvent solution and the dopant solution are combined at 60 to 90 volume percent solvent solution and 40 to 10 volume percent dopant solution.

### BRIEF DESCRIPTION OF THE DRAWINGS

The following detailed description of specific embodiments of the present disclosure can be best understood when read in conjunction with the following drawings.

FIG. (FIG.) 1A illustrates an organic electrochemical transistor schematic with chemical structure of p(g3T2) and oxygen (O₂), according to embodiments herein.

FIG. 1B illustrates an energy level diagram for p(g3T2), O₂, and C₆₀F₄₈, according to embodiments herein.

FIG. 1C is a graph of Ultraviolet photoelectron spectroscopy (UPS) data showing the secondary electron cut-off region of p(g3T2) thin-films prepared with degassed-chloroform and ambient-chloroform, according to embodiments herein.

FIG. 1D is a graph of the Ultraviolet photoelectron spectroscopy HOMO onset region of p(g3T2) thin-films prepared with degassed-chloroform and ambient-chloroform, according to embodiments herein.

FIG. 2A illustrates negative ionization potential of various species, according to embodiments herein.

FIG. 2B illustrates negative ionization potential and electron affinity of various species, according to embodiments herein.

FIG. 3A is a graph of ultraviolet absorption spectra of TES-ADT in degassed-CF, according to embodiments herein.

FIG. 3B is a graph of ultraviolet absorption spectra of TES-ADT in ambient-CF, according to embodiments herein.

FIG. 3C is a graph of maximum intensity of ultraviolet absorption spectra of TES-ADT in degassed-CF and ambient-CF as a function of exposure time, according to embodiments herein.

FIG. 3D is a photograph of TES-ADT solutions prepared with ambient-CF and degassed-CF after 4 minutes of light irradiation, according to embodiments herein.

FIG. 4A is a graph of a p(g3T2) OECT transfer for ambient-CF, according to embodiments herein.

FIG. 4B is a graph of a p(g3T2) OECT transfer for degassed-CF, according to embodiments herein.

FIG. 4C is a schematic of the chemical structure of C₆₀F₄₈, according to embodiments herein.

FIG. 4D is a graph of a p(g3T2) OECT transfer for degassed CF:C₆₀F₄₈(100 mol %), according to embodiments herein.

FIG. 4E is a graph of room temperature electron paramagnetic resonance (EPR) data comparing p(g3T2) solutions prepared from ambient-CF and degassedCF:C₆₀F₄₈(100 mol %), according to embodiments herein.

FIG. 4F is a graph od ultraviolet photoelectron spectroscopy (UPS) which shows the onset of the secondary electron cut-off (SECO) region for the photoelectrons emitted from p(g3T2) thin-films made from solutions prepared with degassed-CF, ambient-CF, and degassedCF:C₆₀F₄₈(100 mol %), according to embodiments herein.

FIG. 4G is a graph of ultraviolet-visible (UV-Vis) absorption data comparing p(g3T2) thin films processed from degassed-CF, ambient-CF, and degassedCF:C₆₀F₄₈(100 mol %), according to embodiments herein.

FIG. 5A is a graph of an output curve for p(g3T2) organic electrochemical transistors prepared with degassed-CF, according to embodiments herein.

FIG. 5B is a graph of an output curve for p(g3T2) organic electrochemical transistors prepared with ambient-CF, according to embodiments herein.

FIG. 5C is a graph of cyclic voltammetry (CV) measurements for p(g3T2), comparing p(g3T2) processed from degassed-CF and ambient-CF, according to embodiments herein.

FIG. 5D is a graph showing statistical charge carrier mobility data for p(g3T2) OECTs processed from degassed-CF and ambient-CF, according to embodiments herein.

FIG. 6A is a graph of an electrochemical impedance spectroscopy curve for p(g3T2) processed from ambient-CF, according to embodiments herein.

FIG. 6B is a graph of an electrochemical impedance spectroscopy curve for p(g3T2) processed from degassed-CF, according to embodiments herein.

FIG. 6C is a graph of an electrochemical impedance spectroscopy curve for p(g3T2) processed from degassed-CF with 100 mol % C₆₀F₄₈, according to embodiments herein.

FIG. 6D is a graph of cyclic voltammetry (CV) measurements using an electrolyte of [BMIM]BF₄, according to embodiments herein.

FIG. 7A is a graph showing statistical charge carrier mobility data for a C₆₀F₄₈ p-doped system, according to embodiments herein.

FIG. 7B is a graph of transfer curves comparing p(g3T2) OECTs processed from ambient-CF, degassed-CF:C₆₀F₄₈(50 mol %) and degassed-CF:C₆₀F₄₈(100 mol %), according to embodiments herein.

FIG. 7C is a graph of the corresponding transconductance peaks to the graph of FIG. 7B, according to embodiments herein.

FIG. 7D is a graph showing threshold voltage (V_{T}) shifts from OECTs prepared with degassed-CF, to OECTs with degassed-CF and C₆₀F₄₈ chemical p-doping, according to embodiments herein.

FIG. 7E is a graph of a representative output curve for degassed-CF:C₆₀F₄₈(50 mol %) OECTs, according to embodiments herein.

FIG. 7F is a graph of a representative output curve for degassed-CF:C₆₀F₄₈(100 mol %) OECTs, according to embodiments herein.

FIG. 8A is a graph of off current increases in p(g3T2) OECTs with C₆₀F₄₈ doping of 0 mol %, according to embodiments herein.

FIG. 8B is a graph of off current increases in p(g3T2) OECTs with C₆₀F₄₈ doping of 300 mol %, according to embodiments herein.

FIG. 8C is a graph of off current increases in p(g3T2) OECTs with C₆₀F₄₈ doping of 600 mol %, according to embodiments herein.

FIG. 9A is a graph of charge carrier mobility (μ) for p(g3T2) OECTs fabricated from degassed-CF, degassed-CF:C₆₀F₄₈(50 mol %), degassed-CF:C₆₀F₄₈(300 mol %) and degassed-CF:C₆₀F₄₈(600 mol %), according to embodiments herein.

FIG. 9B is a graph of μC* for p(g3T2) OECTs fabricated from degassed-CF, degassed-CF:C₆₀F₄₈(50 mol %), degassed-CF:C₆₀F₄₈(300 mol %) and degassed-CF:C₆₀F₄₈(600 mol %), according to embodiments herein.

FIGS. 10A, 10B, and 10C are Atomic force microscopy (AFM) images of surface roughness of p(g3T2) thin-films prepared with ambient-CF, degassed-CF, and degassed-CF:C₆₀F₄₈ respectively, according to embodiments herein.

FIGS. 10D, 10E, and 10F are Grazing Incidence Wide Angle X-ray (GIWAXS) 2D detector images of p(g3T2) thin-films prepared with ambient-CF, degassed-CF and degassed-CF:C₆₀F₄₈(100 mol %), according to embodiments herein.

FIG. 11 is a graph of grazing Incidence Wide Angle X-ray scattering (GIWAXS) 2D of p(g3T2) thin-films, according to embodiments herein.

FIG. 12 is a graph of computerized Fourier transform infrared (FTIR) spectroscopy of p(g3T2) thin-films, according to embodiments herein.

FIG. 13 is a representation of the density functional theory (DFT) computerized vibrational nodes responsible for the infrared peaks market with asterisks in FIG. 12, according to embodiments herein.

FIG. 14 is a graph of Fourier transform infrared (FTIR) spectroscopy of p(g3T2) thin-films, according to embodiments herein.

FIG. 15A is a graph of transfer characteristic for p(g3T2) OECTs measured at drain voltage of −0.6 V processed from ambient-DCB, according to embodiments herein.

FIG. 15B is a graph of transfer characteristic for p(g3T2) OECTs measured at drain voltage of −0.6 V processed from degassed-DCB, according to embodiments herein.

FIG. 15C is a schematic of the chemical structure of C₆₀F₄₈, according to embodiments herein.

FIG. 15D is a graph of transfer characteristic for p(g3T2) OECTs measured at drain voltage of −0.6 V processed from degassed-DCB doped with 100 mol % C₆₀F₄₈, according to embodiments herein.

FIG. 16A is a schematic of the chemical structure of p(g2T2-g4T2), according to embodiments herein.

FIG. 16B is a graph of transfer characteristic for p(g2T2-g4T2) OECTs measured at drain voltage of −0.6 V processed from degassed-CF, according to embodiments herein.

FIG. 16C is a schematic of the chemical structure of C₆₀F₄₈, according to embodiments herein.

FIG. 16D is a graph of transfer characteristic for p(g2T2-g4T2) OECTs measured at drain voltage of −0.6 V processed from degassed-CF doped with 50 mol % C₆₀F₄₈, according to embodiments herein.

FIG. 17A is a schematic of the chemical structure of pgBTTT, according to embodiments herein.

FIG. 17B is a schematic of the chemical structure of B(C₆F₅)₃, according to embodiments herein.

FIG. 17C is a schematic of the chemical structure of C₆₀F₄₈, according to embodiments herein.

FIG. 17D is a graph of pgBTTT OECT transfer curves, where pgBTTT has been processed from ambient-CF, degassed-CF:B(C₆F₅)₃(100 mol %) and degassed-CF:C₆₀F₄₈ (100 mol %), according to embodiments herein.

FIG. 17E is a graph of the maximum transconductance for OECTs fabricated from ambient-CF, according to embodiments herein.

FIG. 17F is a graph of the maximum transconductance for OECTs fabricated from degassed-CF:B(C₆F₅)₃(100 mol %), according to embodiments herein.

FIG. 17G is a graph of the maximum transconductance for OECTs fabricated from degassed-CF:C₆₀F₄₈ (100 mol %), according to embodiments herein.

FIG. 17H is a graph of threshold voltages for OECTs, according to embodiments herein.

FIG. 18A is a graph of 25-hour stability tests comparing on-off ratio (I_{ON/OFF}) degradation as a function of time, in p(g3T2) OECTs processed from ambient-CF and degassed-CF:C₆₀F₄₈(100 mol %), according to embodiments herein.

FIG. 18B is a graph of the initial and final transfer curves for p(g3T2) OECTs processed from ambient-CF in the stability test of FIG. 18A, according to embodiments herein.

FIG. 18C is a graph of the initial transfer curve in the stability test, compared with the 4600^{th} transfer curve in the stability test, for p(g3T2) OECTs processed from degassed-CF:C₆₀F₄₈(100 mol %) of FIG. 18A, according to embodiments herein.

FIG. 18D is a graph of bias stress stability tests in p-type pgBTTT OECTs processed from ambient-CF, where V_{G}=−0.6 V was applied constantly for the 12 h, according to embodiment herein.

FIG. 18E is a graph of bias stress stability tests in p-type pgBTTT OECTs processed from degassed-CF:C₆₀F₄₈(300 mol %), where V_{G}=−0.6 V was applied constantly for the 12 h, according to embodiment herein.

FIG. 18F is a graph of bias stress stability tests in n-type p(C₆NDI-T) OECTs processed from ambient-CF, where V_{G}=0.6 V was applied constantly for the 12 h, according to embodiment herein.

FIG. 18G is a graph of bias stress stability tests in n-type p(C₆NDI-T) OECTs processed from degassed-CF:TBA-OH(400 mol %), where V_{G}=0.6 V was applied constantly for the 24 h, according to embodiment herein.

FIG. 19A is a graph of saturation on current (Iₒₙ) stability tests in p-type pgBTTT OECTs processed from degassed-CF:C₆₀F₄₈(300 mol %), where V_{G}=−0.6 V was applied constantly for the 12 h, according to embodiment herein.

FIG. 19B is a graph of saturation on current (Iₒₙ) stability tests in n-type p(C⁶NDT-T) OECTs processed from degassed-CF:TBA-OH (400 mol %), where V_{G}=0.6 V was applied constantly for the 24 h, according to embodiment herein.

Reference will now be made in greater detail to various embodiments of the present disclosure, some embodiments of which are illustrated in the accompanying drawings.

### DETAILED DESCRIPTION

Embodiments of the present disclosure generally relate to methods of preparing a polymer solution for organic electrochemical transistor preparation. More specifically, the present disclosure provides a method of preparing a polymer solution for organic electrochemical transistor preparation which includes degassing the solvents utilized in the organic electrochemical transistor preparation to remove O₂ and introducing a p-dopant into the polymer solution to chemically dope the organic electrochemical transistor.

Specific embodiments of the present application will now be described. The disclosure may, however, be embodied in different forms and should not be construed as limited to the embodiments set forth in this disclosure. Rather, these embodiments are provided so that this disclosure will be thorough and complete, and will convey the scope of the subject matter to those skilled in the art.

Embodiments of the present disclosure are directed to methods of preparing a polymer solution for organic electrochemical transistor preparation. The method includes preparing a solvent solution; preparing a dopant solution; and combining the solvent solution and the dopant solution at 60 to 90 volume percent solvent solution and 10 to 40 volume percent dopant solution. Further, preparing the solvent solution comprises degassing a first solvent to form a degassed first solvent and combining the degassed first solvent with a polymer and preparing the dopant solution comprises degassing a second solvent to form a degassed second solvent and combining the degassed second solvent with a p-dopant.

Having generally described the method of preparing a polymer solution for organic electrochemical transducer preparation, each of the various components and steps will be provided in further detail. Further, the additional associated steps for manufacturing an organic electrochemical transducer, including processing steps completed before and after coating with the polymer solution will also be discussed for context.

In accordance with various embodiments of the present disclosure, a solvent solution is prepared. The solvent solution includes a first solvent and a polymer. The first solvent is degassed to form a degassed first solvent. Specifically, dissolved gasses, including 02, are removed from the first solvent. As previously noted, O₂ may destabilize formed organic electrochemical transistors so removing the dissolved gasses including O₂ from the solvent solution utilized to form the polymer solution eliminates any detrimental effects of O₂ from the polymer film deposition process.

In one or more embodiments, the first solvent is degassed using a free-pump-thaw degassing process. The freeze-pump-thaw degassing process involves first freezing the first solvent using a Dewar of liquid nitrogen or dry ice. A vacuum is then applied, and the headspace above the frozen first solvent evacuated. This decreases the pressure in the headspace above the liquid, thereby lowering the solubility of the dissolved gas such that the dissolved gas is removed from the first solvent. It will be appreciated that other degassing processes known to those skilled in the art may equally be leveraged to remove O₂, and other dissolved gasses, from the first solvent.

In various embodiments, the first solvent is chloroform or 1,2-dichlorobenzene. Selection of the first solvent should be made to dissolve the polymer into the solvent.

In one or more embodiments, the polymer comprises glycolated polythiophene. Glycolated polythiophenes are a type of conjugated polymer with ethylene glycol side chains attached to a polythiophene backbone. These polymers have an ability to conduct both ions and electrons generating organic mixed ionic-electronic conductors (OMIECs) and are particularly promising for applications as organic electrochemical transistors (OECTs). In various embodiments, the polymer comprises p(g3T2), p(g2T2-g4T2), pgBTTT, or a combination thereof. As would be appreciated by one skilled in the art, p(g3T2) refers to refers to poly(3,3″″-didodecyl-[2,2′:5′,2″-terthiophene]-5,5″-diyl). Similarly, p(g2T2-g4T2) refers to a glycolated polythiophene and more specifically a copolymer composed of two monomers: g2T2 and g4T2 with g2T2 and g4T2 respectively representing a polymer of thiophene rings with ethylene glycol (EG) side chains of two EG units and four EG units. Finally, pgBTTT represents (poly(2-(4,4′-bis(2-methoxyethoxy)-5′-methyl-[2,2′-bithiophen]-5-yl)-5-methylthieno[3,2-b]thiophene)).

The first solvent and the polymer may be provided in various combinations. For example, in various embodiments, the first solvent and polymer combinations may comprise chloroform with p(g3T2), chloroform with p(g2T2-g4T2), chloroform with pgBTTT, 1,2-dichlorobenzene with p(g3T2), or other combinations of the disclosed first solvent and polymer.

In one or more embodiments, the solvent solution comprises 2 to 10 mg of the polymer per ml of the solvent solution. In various further embodiments, the solvent solution comprises 2 to 8 mg of the polymer per ml of the solvent solution, 3 to 10 mg of the polymer per ml of the solvent solution, 3 to 7 mg of the polymer per ml of the solvent solution, 4 to 6 mg of the polymer per ml of the solvent solution, or approximately 5 mg of the polymer per ml of the solvent solution.

In accordance with various embodiments of the present disclosure, a dopant solution is prepared. The dopant solution includes a second solvent and a p-dopant. A p-dopant is an impurity added to a semiconductor to create vacancies or holes where electrons should be, thus increasing its ability to conduct electricity by allowing these holes to move. The second solvent is degassed to form a degassed second solvent. Specifically, dissolved gasses, including O₂, are removed from the second solvent. As previously noted, O₂ may destabilize formed organic electrochemical transistors so removing the dissolved gasses including O₂ from the dopant solution utilized to form the polymer solution eliminates any detrimental effects of O₂ from the polymer film deposition process.

In one or more embodiments, the second solvent is degassed using a free-pump-thaw degassing process. The freeze-pump-thaw degassing process is the same as described with regards to the first solvent. It will be appreciated that other degassing processes known to those skilled in the art may equally be leveraged to remove O₂, and other dissolved gasses, from the second solvent.

In one or more embodiments, the second solvent is chlorobenzene.

In one or more embodiments, the p-dopant comprises fluorinated fullerene (C₆₀F₄₈), tris(pentafluorophenyl)borane (B(C₆F₅)₃), tributyl ammonium hydroxide (TBA-OH), or a combination thereof.

In one or more embodiments, the solvent solution and the dopant solution are combined together to form the polymer solution. In various embodiments, the solvent solution and the dopant solution are combined at 60 to 90 volume percent solvent solution and 10 to 40 volume percent dopant solution, 70 to 90 volume percent solvent solution and 10 to 30 volume percent dopant solution, 75 to 85 volume percent solvent solution and 15 to 25 volume percent dopant solution, or approximately 80 volume percent solvent solution and 20 volume percent dopant solution.

The composition of the solvent solution and the dopant solution may be provided in various combinations to form polymer solutions with various combinations of the polymer and the p-dopant. For example, in various embodiments, the polymer and p-dopant combinations may comprise p(g3T2) with C₆₀F₄₈, p(g2T2-g4T2) with C₆₀F₄₈, or pgBTTT with B(C₆F₅)₃. While specific examples of polymer and p-dopant combinations are provided, it is noted that all combinations of the disclosed polymers and p-dopants may be utilized.

In one or more where p(g3T2) is provided in combination with C₆₀F₄₈, the C₆₀F₄₈ may be provided at a 0.5:1 to 6:1 molar ratio relative to the p(g3T2). In various further embodiments, the C₆₀F₄₈ may be provided at a 0.5:1 to 3:1 molar ratio relative to the p(g3T2), at a 1:1 to 6:1 molar ratio relative to the p(g3T2), at a 3:1 to 6:1 molar ratio relative to the p(g3T2), or at a 0.5:1 to 3:1 molar ratio relative to the p(g3T2). It is noted that such molar ratios may alternatively be referenced by reciting the mol % concentration of the C₆₀F₄₈ relative to the polymer. For example, indication of a p(g3T2):C₆₀F₄₈ doped solution prepared at a 300 mol % concentration represents a solution with 3 times the moles of C₆₀F₄₈ than p(g3T2). The same convention extends to other combinations of polymer and p-dopant.

In one or more where p(g2T2-g4T2) is provided in combination with C₆₀F₄₈, the C₆₀F₄₈ may be provided at a 0.2:1 to 1:1 molar ratio relative to the p(g2T2-g4T2). In various further embodiments, the C₆₀F₄₈ may be provided at a 0.2:1 to 0.5:1 molar ratio relative to the p(g2T2-g4T2) or at a 0.5:1 to 1:1 molar ratio relative to the p(g2T2-g4T2).

Various embodiments of the present disclosure also include polymer solutions for organic electrochemical transistor preparation which were prepared according to embodiments of the disclosure methods. Specifically, in one or more embodiments a polymer solution for organic electrochemical transistor preparation comprises a solvent solution comprising a degassed first solvent and a polymer and a dopant solution comprising a degassed second solvent and a p-dopant, wherein the solvent solution and the dopant solution are combined at 60 to 90 volume percent solvent solution and 10 to 40 volume percent dopant solution. In one or more specific embodiments the first solvent is chloroform or 1,2-dischlorobenzene; the second solvent is chlorobenzene; and the polymer comprises a glycolated polythiophene. Further, in one or more specific embodiments the p-dopant comprises fluorinated fullerene (C₆₀F₄₈), tris(pentafluorophenyl)borane (B(C₆F₅)₃), tributyl ammonium hydroxide (TBA-OH), or a combination thereof.

### EXAMPLES

To demonstrate the feasibility and utility of preparing polymer solutions for organic electrochemical transistor preparation and improved organic electrochemical transistors formed utilizing the same, various experimental tests were completed.

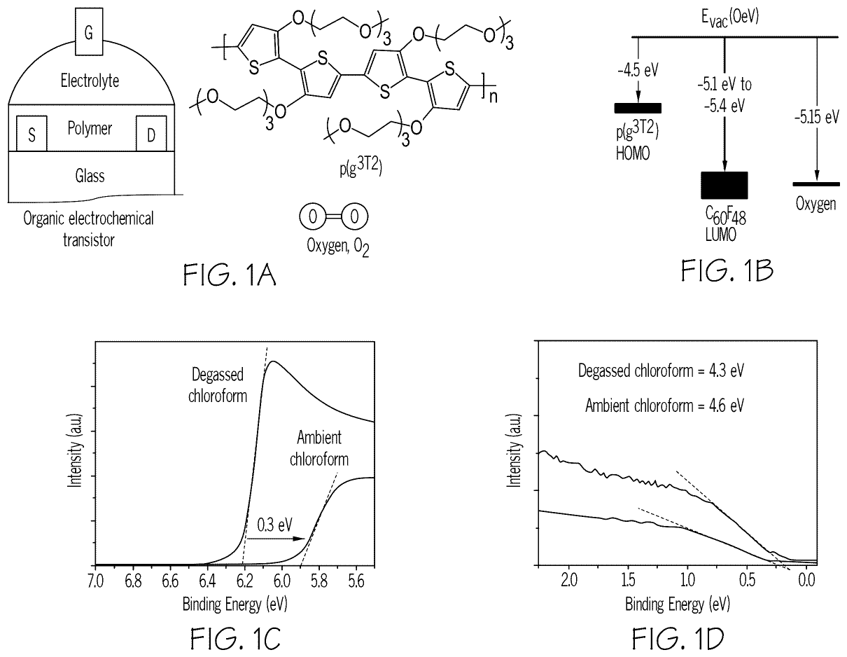

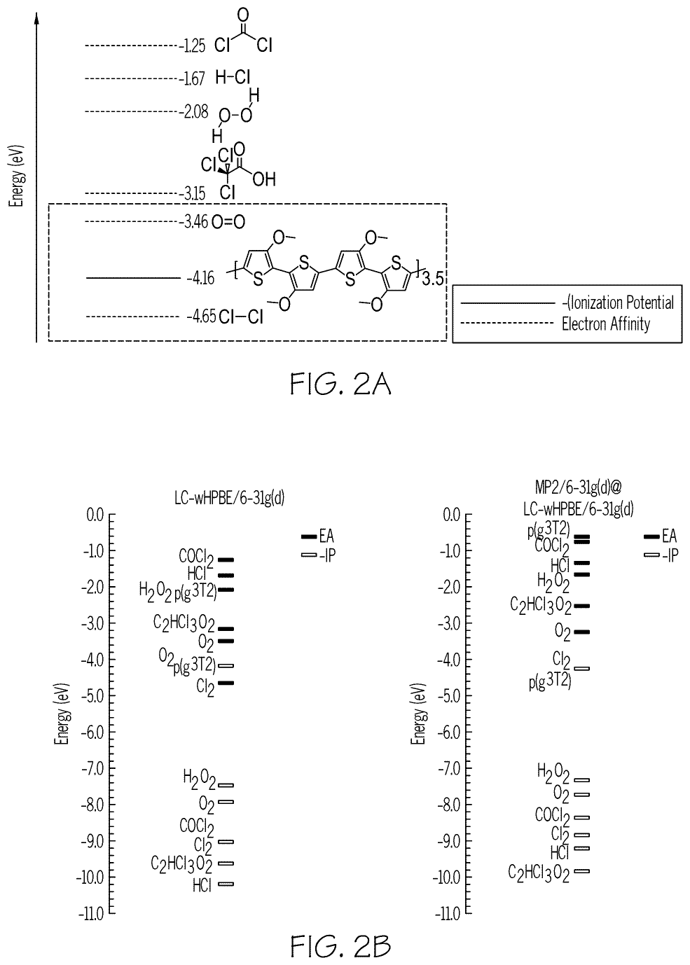

It is believed that O₂ p-doping is possible in organic electronics. For example, it has been anecdotally noticed that leaving p-type organic devices outside a controlled environment with exposure to ambient air and conditions for a day before testing will enhance the performance of the device. O₂ is present in dissolved quantities in solvents exposed to air, such as chloroform (CF). To determine and verify that 02 acts as a p-dopant, tests were completed for ambient and degassed solvents in formation of OMIECs, Specifically, Applicant degassed CF using a freeze-pump-thaw method to explore whether O₂ dissolved in CF acts as a p-dopant, in representative p-type polyethylene glycol functionalized OMIEC, p(g3T2). The generalized structure is presented in FIG. 1A. The ionization energy (IE) of 4.46 eV for p(g3T2) is shown in FIG. 1B along with the IE for C₆₀F₄₈ and O₂. The effect of degassing and removing 02 is illustrated in FIGS. 1C and 1D which compare p(g3T2) processed from degassed-CF with p(g3T2) processed from CF stored in air (ambient-CF) using Ultraviolet photoelectron spectroscopy (UPS). UPS indicates that the p(g3T2) processed from ambient-CF is more p-doped than the film processed from degassed-CF. Specifically, the work function shifts from 4.0 eV for the degassed-CF p(g3T2) to 4.3 eV for the p(g3T2) ambient-CF, and p(g3T2) has a larger IE (4.6 eV) when processed using ambient-CF compared to degassed-CF (4.3 eV). To confirm O₂ is the primary p-dopant, rather than other volatile species removed during degassing, Applicant used density functional theory (DFT) and an oxygen sensor. DFT was first used to explore molecules that will spontaneously oxidize p(g3T2), that is molecules with a lower electron affinity (EA) than the negative ionization energy (IE) of p(g3T2). Based on the proximity of their EA to the p(g3T2) IE, FIGS. 2A and 2B indicate the thermodynamics are favorable for O₂ to behave as a p-dopant, and that chlorine gas may possibly oxidize p(g3T2). It is noted that FIG. 2B includes a boxed region indicating a 1 eV threshold set to account for DFT electron self-interaction error.

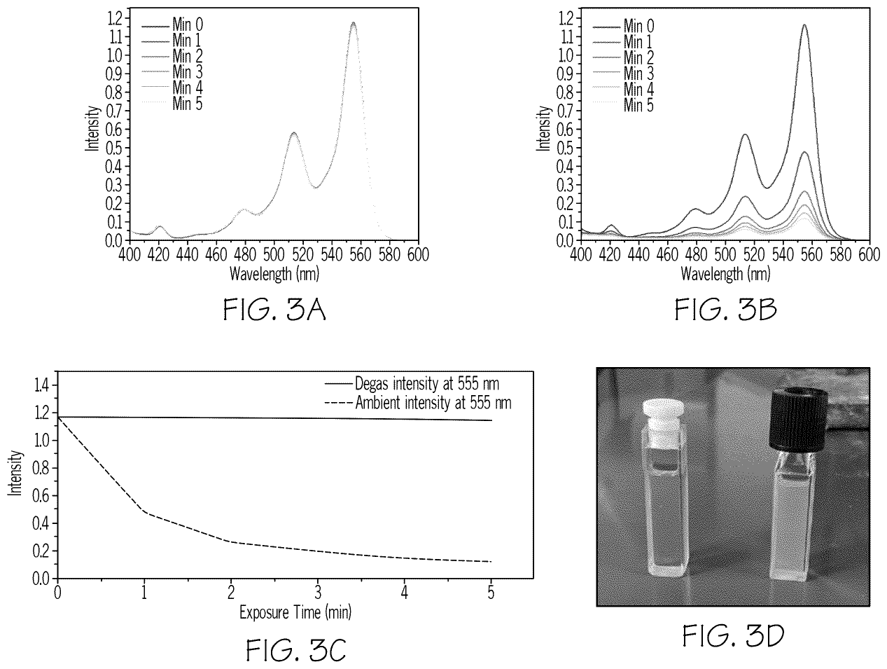

To confirm O₂ is present in the ambient-CF but not present in the degassed-CF a 5,11-bis(triethylsilylethynyl)anthradithiophene (TES-ADT) oxygen sensor was utilized. Specifically, TES-ADT will only undergo a chemical reaction with photogenerated singlet oxygen in ambient-CF, and not in degassed-CF. The reaction between TES-ADT and oxygen results in loss of absorbance with elongated light irradiation. With reference to FIG. 3A ultraviolet (UV) absorption spectra of TES-ADT in degassed-CF and with reference to FIG. 3B UV absorption spectra of TES-ADT in ambient-CF are provided. Both FIGS. 3A and 3B represent measurement at one-minute intervals from the start of the light illumination. With reference to FIG. 3C, maximum intensity of the UV absorption spectra for TES-ADT in degassed-CF and ambient-CF is provided as a function of light exposure time. Intensity was taken at 555 nm wavelength. The data shows that UV absorption for the TES-ADT in ambient-CF decreases in intensity, with almost full degradation of the acene sensor material after 5 minutes. This demonstrates that TES-ADT in ambient-CF undergoes photo-oxidation, which is a reaction that can only happen if oxygen is present in the ambient-CF. On the other hand, the TES-ADT in degassed-CF maintains the same absorption over time, and therefore the photo-oxidation does not happen in degassed-CF because there is no oxygen present. FIG. 3D provides photographs showing cuvettes containing TES-ADT solutions prepared with ambient-CF (left) and degassed-CF chloroform (right) after 4 minutes of light irradiation. Comparing absorption spectra in ambient-CF and degassed-CF before and after light irradiation demonstrates oxygen is removed in the degassing process, and that oxygen is present in ambient-CF to act as a p-dopant in p(g3T2) OECTs.

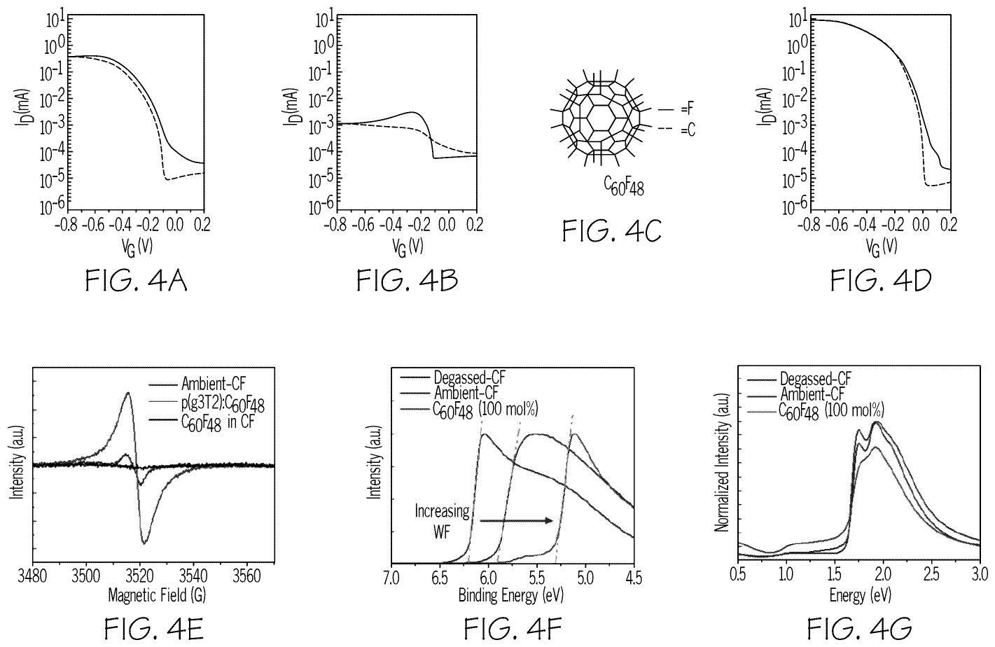

As p-doping plays an important role in transistor performance, Applicant explored the impact of O₂ p-doping on p(g3T2) OECTs. OECTs were measured in a nitrogen glovebox using an ionic liquid, 1-butyl-3-methylimidazolium tetrafluoroborate, [BMIM][BF₄], as the electrolyte, to avoid introducing other sources of O₂ and allow focus only on the impact of removing O₂ from the solvent. With reference to FIGS. 4A, 4B, and 4D, representative p(g3T2) OECT transfer curves measured at V_{D}=−0.6 V are presented. FIG. 4A represents ambient-CF, FIG. 4B represents degassed-CF, and FIG. 4D represents degassed CF:C₆₀F₄₈(100 mol %). It is noted the structure of C₆₀F₄₈ is provided in FIG. 4C. The generated OECTs were tested at a 0.52 V/s scan rate with a [BMIM]I[BF₄] electrolyte, in a nitrogen filled glovebox, to remove O₂ and focus the study only on O₂ p-doping occurring because of dissolved O₂ in ambient-CF. A review of FIGS. 4A and 4B illustrates that degassed-CF reduces the on-current (I_{ON}) by three orders of magnitude, and the corresponding transconductance (gₘ) for the transistors reduces from 1.6 mS to 0.18 mS.

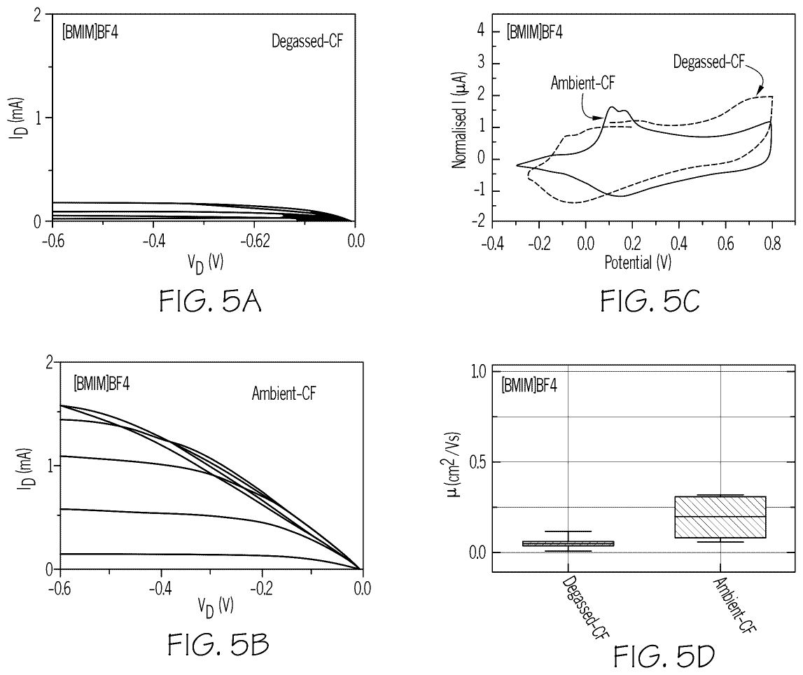

Output curves for p(g3T2) organic electrochemical transistors prepared with degassed-CF are provided in FIG. 5A and prepared with ambient-CF are provided in FIG. 5B. Further, cyclic voltammetry (CV) measurements for p(g3T2), comparing p(g3T2) processed from degassed-CF and ambient-CF is provided in FIG. 5C. V_{G} was measured from 0 V to −0.6V at 0.12 V intervals with data collected at a scan rate of 0.28 V/s. However, FIG. 5D indicates that, while ambient-CF outperforms degassed-CF, statistically across 6 OECTs, charge carrier mobility (p) values are not remarkably dissimilar.

To approach the challenge of retaining trap filling effects, while enhancing OECT performance and removing O₂ that causes instability, Applicant identified a chemical p-dopant. For testing, fluorinated fullerene, C₆₀F₄₈ was selected as the p-dopant as such has favorable energetics for p(g3T2), and once it has reacted to p-dope the host OMIEC, it is unlikely to impart additional chemistry to the polymer. FIG. 4D shows the results for degassed-CF:C₆₀F₄₈ OECTs at 100 molar weight percentage (mol %), where the mol % of C₆₀F₄₈ was calculated as a percentage of the total molar mass of p(g3T2) in a 5 mg/ml solution. There was a substantial, four orders of magnitude increase in I_{ON}, and a remarkable maximum I_{ON/OFF} ˜1.4×10⁶, with an average I_{ON/OFF}≈3.3×10⁵ over six OECTs. In the most extreme case between the transistors tested in FIGS. 4B and 4C, gₘ increased by over 100 fold, from 0.18 mS to 25.1 mS.

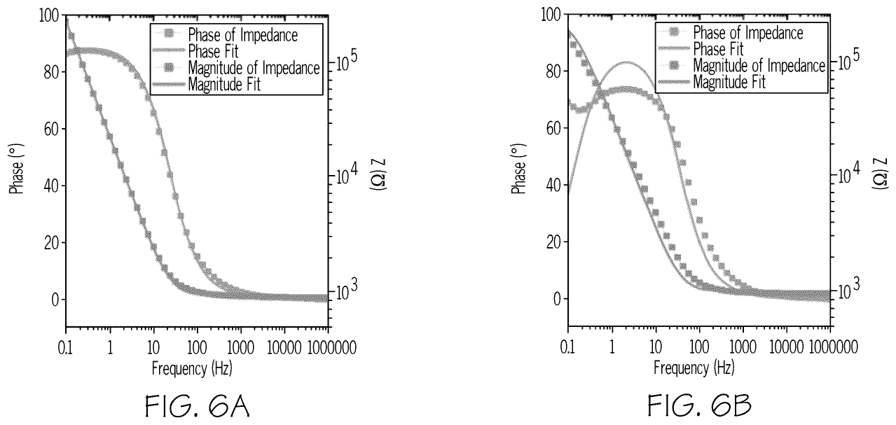

To quantify the μC* product, the volumetric capacitance (C*) was measured by fitting electrochemical impedance spectroscopy (EIS) data FIGS. 6A through 6D. Specifically, electrochemical impedance spectroscopy (EIS) curves for p(g3T2) processed from ambient-CF, degassed-CF, and degassed-CF with 100 mol % C₆₀F₄₈ are provided in FIGS. 6A, 6B, and 6C respectively. The films were measured with an ionic liquid, [BMIM]BF₄, as the electrolyte, using a platinum wire as the counter electrode, and a 500×500 μm gold (Au) electrode coated with p(g3T2) as the reference and working electrodes. The EIS data was taken with a DC offset voltage equivalent to the maximum transconductance voltage, vs. a 500×500 μm polymer coated Au electrode. The equivalent circuit model Rₛ(RP∥C) was used to fit the impedance spectra to extract capacitance, which was in turn used to calculate the volumetric capacitance (C*). FIG. 6D provides cyclic voltammetry (CV) measurements taken at a scan rate of 0.05 V/s with the electrolyte [BMIM]BF₄.

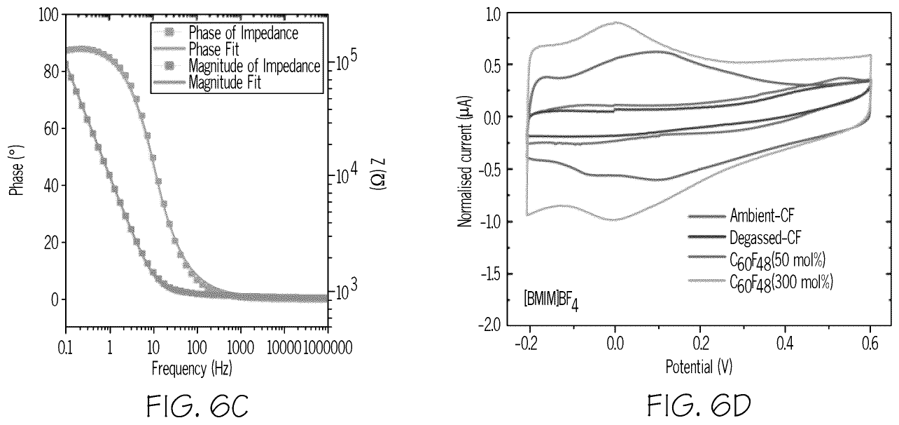

An overview of the impact of the two-step technique of degassed-CF combined with C₆₀F₄₈ chemical p-doping on p(g3T2) OECT performance is provided by FIGS. 7A through 7F. With reference to FIG. 7A, a box-and-whisker plot showing statistical charge carrier mobility data, for six OECTs per system, indicating the median center line, upper quartile box limit, lower quartile box limit and whiskers, as well as outlier for the C₆₀F₄₈ p-doped system is provided. Mobility was calculated from the peak in the transconductance. With reference to FIG. 7B, transfer curves measured at V_{D}=−0.6 V comparing p(g3T2) OECTs processed from ambient-CF, degassed-CF:C₆₀F₄₈(50 mol %) and degassed-CF:C₆₀F₄₈(100 mol %) are provided with FIG. 7C providing the corresponding transconductance peaks. FIG. 7D demonstrates how the threshold voltage (V_{T}) shifts from OECTs prepared with degassed-CF, to OECTs with degassed-CF and C₆₀F₄₈ chemical p-doping. Specifically, FIG. 7D shows V_{T} shifts towards 0 V, from average values of −0.13 V to −0.08 V, in the degassed-CF and degassed-CF:C₆₀F₄₈ OECTs, respectively, that is characteristic of doped transistors. FIGS. 7E and 7F provide representative output curve for degassed-CF:C₆₀F₄₈(50 mol %) OECTs and for degassed-CF:C₆₀F₄₈(100 mol %) OECTs respectively. The output curves correspond to the transfer curves shown in FIG. 7B. Output curves were measured from V_{G}=0 to V_{G}=−0.8 V at intervals of ΔV_{G}=0.12 V. OECT channel length and width are 50 μm and 500 m, respectively, and were tested with [BMIM]BF₄ electrolyte in a nitrogen glovebox in a bottom-gate, bottom-contact structure with a 500 μm×500 μm polymer coated gold electrode as the gate. Overall, chemical doping clearly has a significant impact on OECT performance metrics.

EPR, UPS and ultraviolet-visible absorbance (UV-Vis) were used to confirm that C₆₀F₄₈ indeed acts as a p-dopant.

With reference to FIG. 4E, room temperature electron paramagnetic resonance (EPR) comparing 5 mg/mL p(g3T2) solutions prepared from ambient-CF and degassedCF:C₆₀F₄₈(100 mol %), indicate that C₆₀F₄₈ is a more effective p-dopant than O₂. Data for pristine C₆₀F₄₈ is also shown. Specifically, the EPR of FIG. 4E shows a distinct increase in EPR signal, indicating C₆₀F₄₈ increases the number of unpaired electrons in p(g3T2). FIG. 4F provides ultraviolet photoelectron spectroscopy (UPS) which shows the onset of the secondary electron cut-off (SECO) region for the photoelectrons emitted from p(g3T2) thin-films made from solutions prepared with degassed-CF, ambient-CF, and degassedCF:C₆₀F₄₈(100 mol %). The work function (WF) is determined by the difference between the intersection of the linear fit to the SECO edge with the background (dashed lines) and the photon energy (hv) of the UV source, where hv=10.2 eV, and therefore WF=10.2−SECO. Specifically, the UPS data in FIG. 4F shows C₆₀F₄₈ is a more effective p-dopant than 02, through a systematic increase in the work function from 4.0 eV, 4.3 eV, to 4.9 eV, for degassed-CF, ambient-CF, and degassed-CF:C₆₀F₄₈ (100 mol %), respectively. Additionally, the HOMO onset shifts towards the Fermi energy in order of degassed-CF, ambient-CF, and degassed-CF:C₆₀F₄s (100 mol %). Finally, with reference to FIG. 4G, ultraviolet-visible (UV-Vis) absorption comparing p(g3T2) thin films processed from degassed-CF, ambient-CF, and degassedCF:C₆₀F₄₈(100 mol %) is provided. The UV-Vis-NIR absorbance further supports the positive effect of doping as the polaron/bipolaron absorbance between 1.6 eV and 0.5 eV increases in intensity in the same order (degassed-CF, ambient-CF, and degassed-CF:C₆₀F₄₈ (100 mol %)). A decrease in absorbance/peak intensity at ˜2.2 eV is consistent with polaron/bipolaron formation, indicating reduction in the neutral state with C₆₀F₄₈.

The provided EPR, UPS and UV-Vis of FIGS. 4E, 4F, and 4G confirm that p-doping mechanisms underpin OECT V_{T} shift, increase in p, and increase in the μC* product: C₆₀F₄₈ p-dopes via integer charge transfer to accept electrons from the host, donating holes that first fill deep and shallow localized trap states, and, once filled, the donated holes are free carriers in delocalized states. Therefore, V_{T} shifts because it is the V_{G} required to fill the trap states, and I_{ON} increases from a higher carrier density.

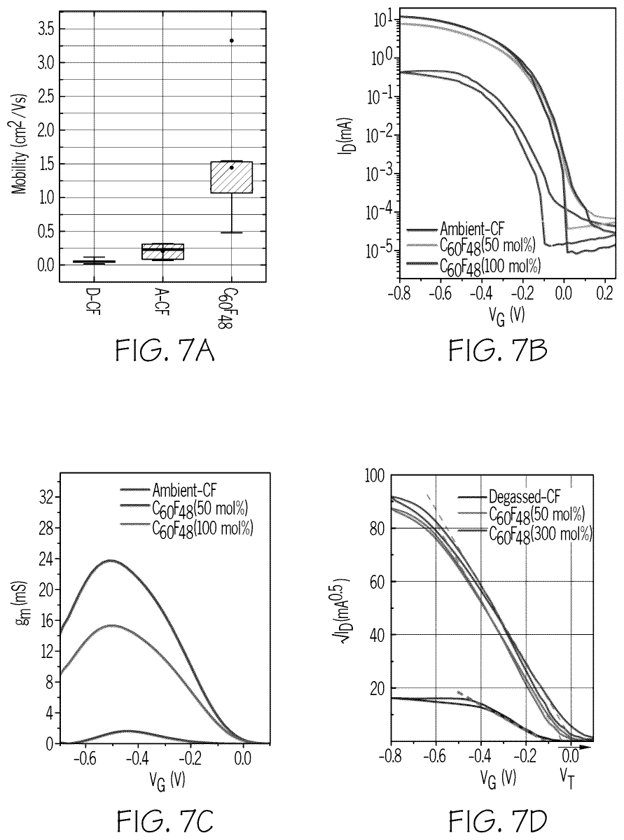

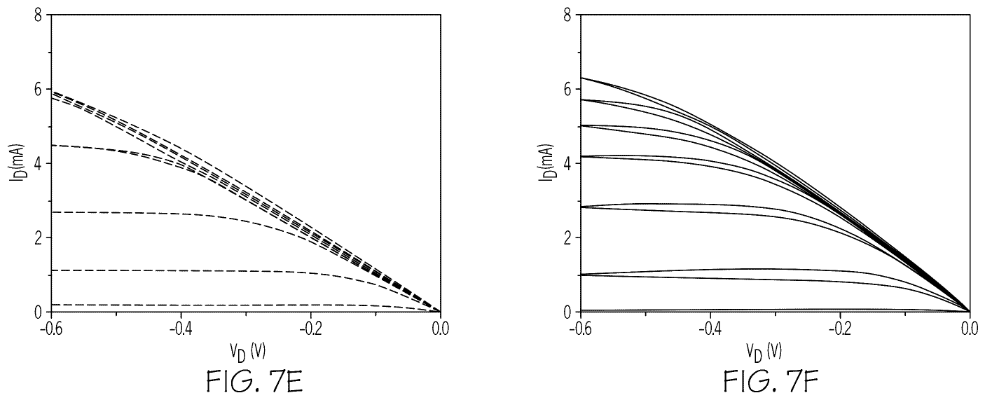

Further evidence that C₆₀F₄₈ is an effective chemical p-dopant includes (i) the increase in I_{OFF} illustrated in FIGS. 8A through 8C at very high doping concentrations because C₆₀F₄₈ increases OMIEC conductivity, and (ii) the decrease in μ and the μC* product illustrated in FIGS. 9A and 9B because very high dopant concentrations can introduce scattering. Specifically, FIGS. 8A, 8B, and 8C provide off current increases in p(g3T2) OECTs with C₆₀F₄₈ doping of 0 mol %, 300 mol %, and 600 mol % respectively. The increase in the off-current occurs because the high C₆₀F₄₈ concentration increases conductivity of the polymer, and reduces the difference between the off-current and on-current. Increase in off-current is a classic behavior of doped transistors, and further supports the electron paramagnetic resonance and ultraviolet photoelectron spectroscopy results in terms of the effectiveness of C₆₀F₄₈ as a p-dopant for p(g3T2). Further the box-and-whisker plots compare charge carrier mobility (μ) in FIG. 9A, and the μC* product in FIG. 9B, extracted from the transconductance for p(g3T2) OECTs fabricated from degassed-CF, degassed-CF:C₆₀F₄₈(50 mol %), degassed-CF:C₆₀F₄₈(300 mol %) and degassed-CF:C₆₀F₄₈(600 mol %). The median center line, upper and lower quartile box limits, whiskers and outliers are shown. The data shows that μ and the μC* product increase with C₆₀F₄₈ concentration, and decrease at very high doping concentrations of 600 mol %. This typically happens in highly doped transistors because structural disorder and scattering decrease.

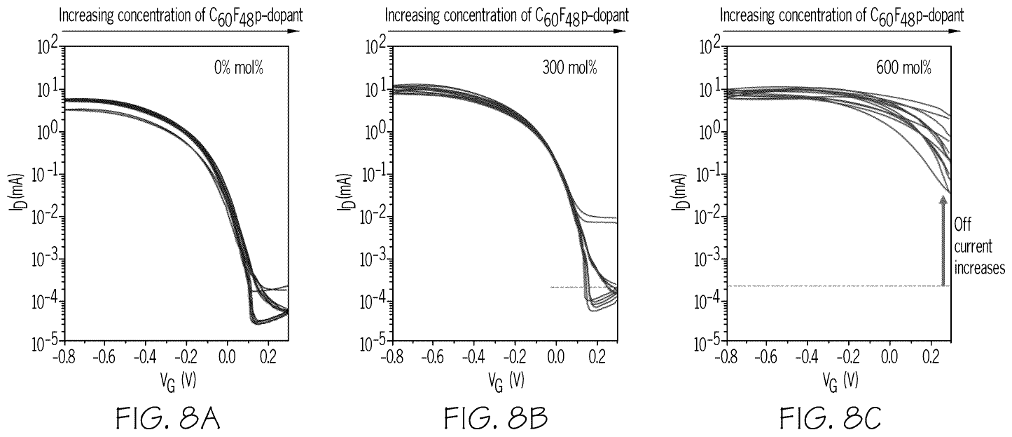

Improvements in p and therefore the μμC* product can occur because structural changes occur synergistically with the p-doping shown in EPR, UPS and UV-Vis. Atomic force microscopy (AFM) and grazing-Incidence wide-angle X-ray scattering (GIWAXS) were used to elucidate differences in p(g3T2) thin-film morphology and structure when processed from degassed-CF, ambient-CF and degassed-CF:C₆₀F₄₈. With reference to FIGS. 10A through 10C, AFM show reduced surface roughness for degassed-CF:C₆₀F₄₈ compared to ambient-CF and degassed-CF. Specifically, ambient-CF and degassed-CF have root mean squared (RMS) roughness values of 14.8 nm and 18.5 nm, respectively, compared to 2.2 nm for degassed-CF:C₆₀F₄₈.

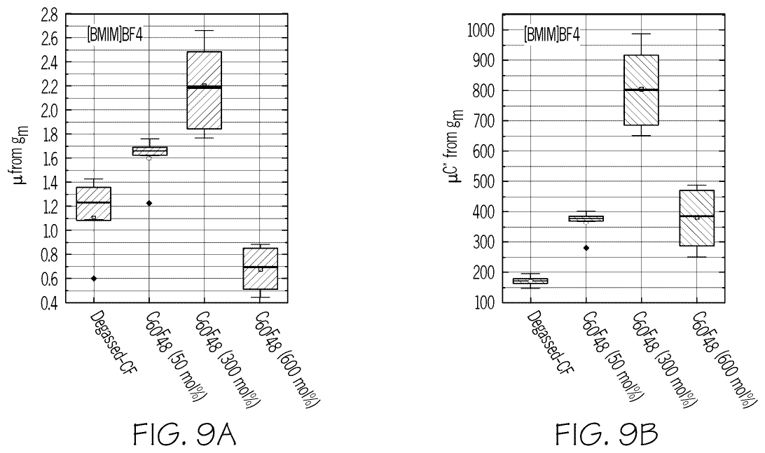

Grazing Incidence Wide Angle X-ray (GIWAXS) 2D detector images of p(g3T2) thin-films prepared with ambient-CF, degassed-CF and degassed-CF:C₆₀F₄₈(100 mol %) are provided as FIGS. 10D, 10E, and 10F respectively. The thickness of the p(g3T2) thin-films are 108 nm, 101 nm, and 33 nm for ambient-CF, degassed-CF and degassed-CF:C₆₀F₄₈(100 mol %), respectively. Thicknesses are average values taken from 5 values measured with a Dektak. (g) Corresponding in plane line cut of the GIWAXS data. The grazing Incidence Wide Angle X-ray (GIWAXS) 2D detector images of p(g3T2) thin-films supports the AFM data by showing similar structures for degassed-CF and ambient-CF p(g3T2) thin-films, and comparatively dramatic structural changes in degassed-CF:C₆₀F₄₈. First, FIGS. 10D and 10E shows p(g3T2) thin-films processed from ambient-CF and degassed-CF films are qualitatively similar, adopting a predominantly edge on orientation with out of plane lamellar stacking peaks. However, it is noted the degassed-CF lattice is tighter in real space, and the ambient-CF lattice spacing has expanded by 4%; ambient-CF lattice shifts to lower q, and quantitative analysis fitting of the (100) lamellar peak in FIG. 11 reveals a 4% expansion that suggests ambient-CF film is lightly p-doped relative to degassed-CF. Second, FIGS. 10E, 10F, and 10G shows degassed-CF:C₆₀F₄₈ has stronger out of plane scattering at 1.7 A⁻¹, consistent with a dramatic increase in the π-π stacking, relative to both ambient-CF and degassed-CF. The significant increase in π-crystallinity may be because there are a greater number of delocalised charge carriers in p(g3T2) processed from degassed-CF:C₆₀F₄₈. It is worth noting that this additional scattering is out of plane, and therefore originates from a different population of crystallites, than the predominantly edge on morphology mentioned above.

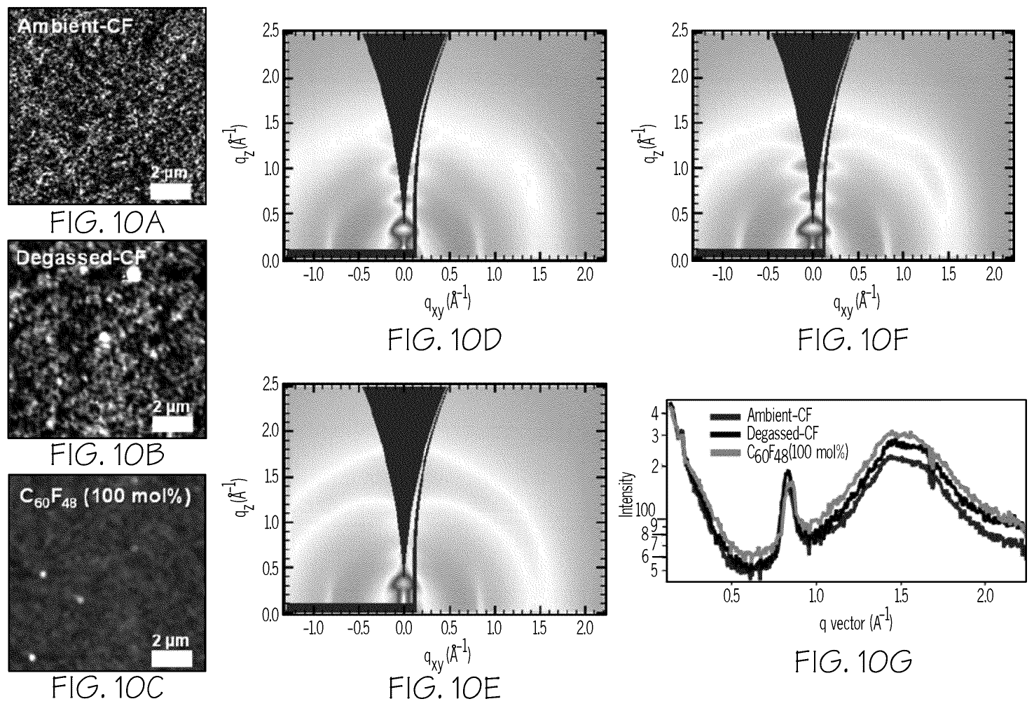

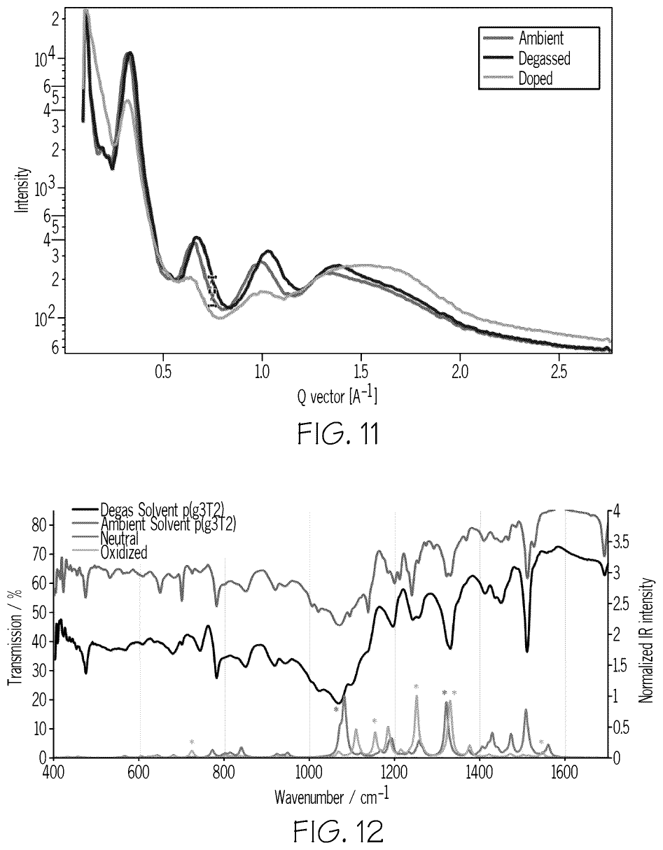

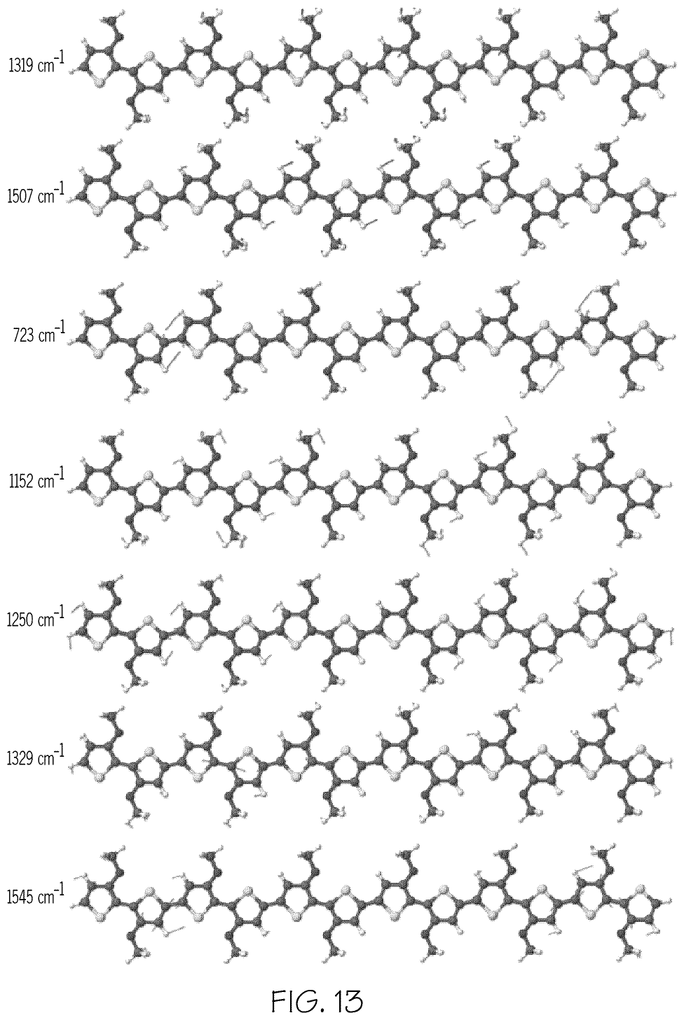

While EPR, UPS and UV-Vis show that C₆₀F₄₈ is a more effective p-dopant than O₂, and AFM and GIWAXS show C₆₀F₄₈ changes the structure, it is difficult to disentangle whether p-doping or structural changes are the dominant mechanism underpinning the superior OECT performance. Accordingly, experimental and comparative computerized Fourier transform infrared (FTIR) spectroscopy as illustrated in FIG. 12 were used to elucidate contributions from synergistic morphology changes and p-doping. Computed spectra (scaled B3LYP/6-31G*) of neutral p(g3T2) show only FTIR from thin-films processed from degassed-CF agree with the neutral state. On the other hand, computed spectra of oxidized p(g3T2) show good agreement between the new peaks measured in ambient-CF and degassed-CF:C₆₀F₄₈ FTIR and the oxidized state. The vibrational modes are a combination of C═C stretches in the polymer backbone, accompanied by C—H oscillations, or involvement from the truncated alkoxy chains as illustrated in FIG. 13. The new peaks in ambient-CF are well-aligned with those in degassed-CF:C₆₀F₄s as illustrated in FIG. 14, suggesting that FTIR changes are unlikely to be structural because they are not drastically different for the large fullerene dopant, compared to a small O₂ molecule. The latter indicates p-doping mechanisms may be more dominant for OECT performance, compared to structural changes.

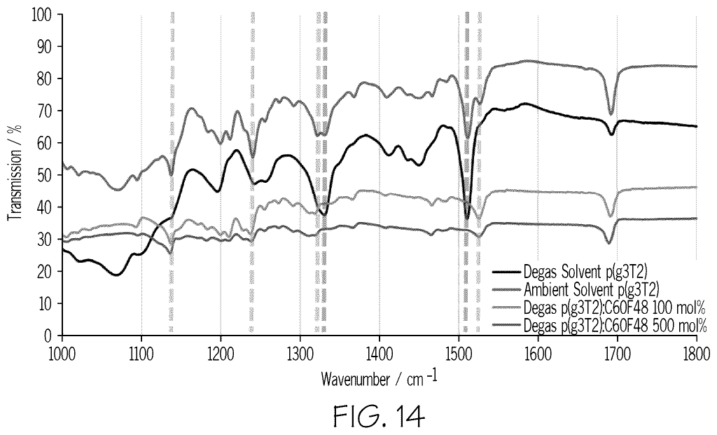

The generality of the combined chemical doping and solvent-degassing technique was verified and demonstrated by testing other material systems. First, a different solvent, 1,2-dichlorobenzene (DCB), was used with p(g3T2) as illustrated in FIGS. 15A through 15D. Transfer characteristics are shown for p(g3T2) OECTs measured at drain voltage=−0.6 V when processed from ambient-DCB, degassed-DCB, and degassed-DCB p-doped with 100 mol % of C₆₀F₄₈, in FIGS. 15A, 15B, and 15D respectively. FIG. 15C illustrates the chemical structure of the C₆₀F₄₈ used as a p-dopant. All measurements used the ionic liquid electrolyte, [BMIM]BF₄. Ambient-DCB OECTs illustrated in FIG. 15A has high I_{OFF}, demonstrating they are p-doped, while degassed-DCB illustrated in FIG. 15B had reduced I_{OFF} and shifted V_{T}, showing that degassed-DCB OECTs are less doped when 02 is removed from the solvent. C₆₀F₄₈ further enhanced the transistor with a sharper subthreshold slope (SS) and turn on, indicating a more pronounced gₘ. Accordingly, it is believed the differences in DCB and CF suggests that oxygen is a more effective dopant when the solvent is DCB, compared to CF. That is, p-doping from oxygen increases I_{ON} in OECTs processed from CF, yet decreases I_{OFF} in DCB.

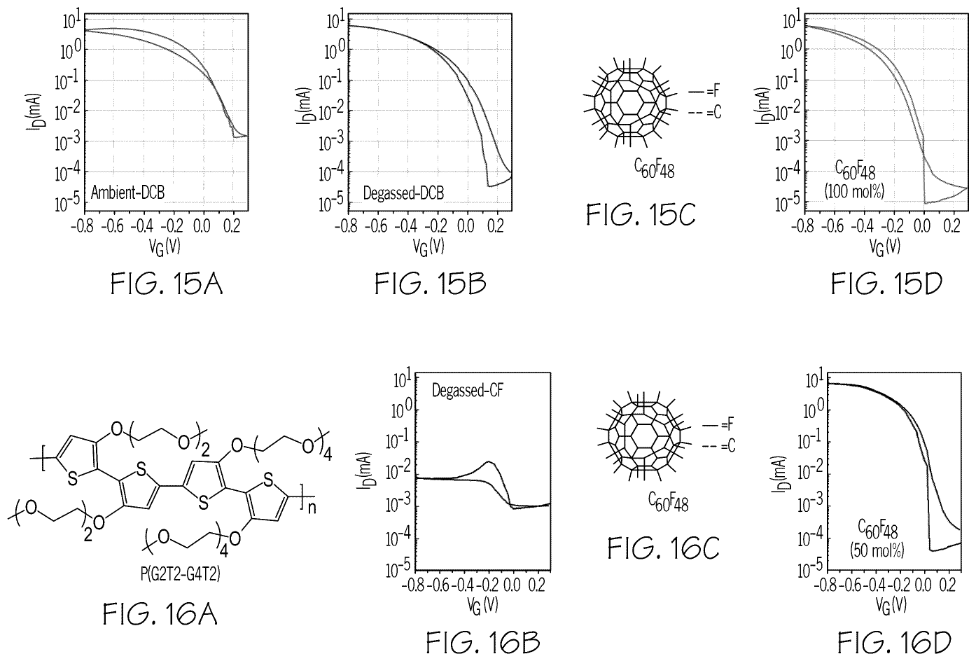

A further polymer, glycolated polythiophene p(g2T2-g4T2) was processed from degassed-CF and degassed-CF:C₆₀F₄₈ and tested in inert conditions. FIG. 16B provides transfer characteristics for p(g2T2-g4T2) OECTs prepared with degassed-CF and FIG. 16D provides transfer characteristics for p(g2T2-g4T2) OECTs prepared with degassed-CF:C₆₀F₄₈(50 mol %). The transfer curves are tested at V_{D}=−0.6 V. Further, the OECTs were tested in a nitrogen-filled glove box in a bottom-gate bottom-contact transistor architecture with a 500×500 μm p(g2T2-g4T2) coated gold electrode as the gate electrode, and [BMIM]BF₄ as the electrolyte. It is noted, FIGS. 16A and 16C provide the chemical structure of glycolated polythiophene p(g2T2-g4T2) and C₆₀F₄₈ p-dopant, respectively. FIGS. 16B and 16D illustrate the same trends as p(g3T2) in FIGS. 4B and 4D with degassing CF and p-doping with C₆₀F₄₈ in the most extreme case resulting in a three order of magnitude increase in I_{ON}, a corresponding gₘ increases from 0.02 to 16.4 mS, and improved I_{ON/OFF} ratio.

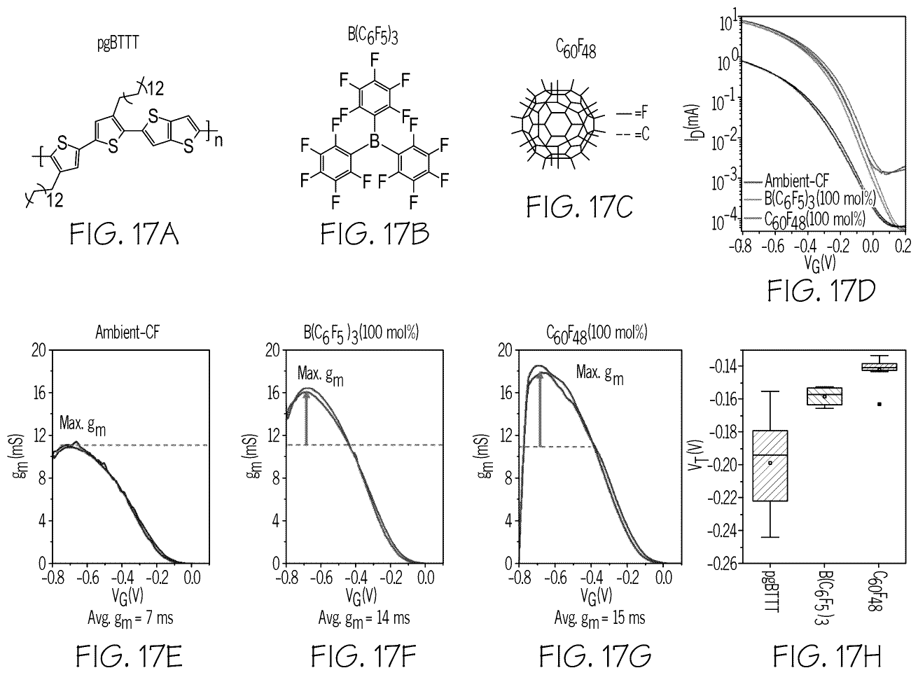

A further polymer, pgBTTT and another p-dopant, B(C₆F₅)₃ were tested. Specifically, pgBTTT OECTs were p-doped with two p-dopants, tris(pentafluorophenyl)borane (B(C₆F₅)₃) and C₆₀F₄₈. The chemical structure of pgBTTT is provided in FIG. 17A, the chemical structure of B(C₆F₅)₃ is provided in FIG. 17B, and the chemical structure of C₆₀F₄₈ is provided in FIG. 17C. FIG. 17D provides the transfer characteristics for each sample. Specifically, FIG. 17D provides pgBTTT OECT transfer curves, where pgBTTT has been processed from ambient-CF, degassed-CF:B(C₆F₅)₃(100 mol %) and degassed-CF:C₆₀F₄₈ (100 mol %). Each of FIGS. 17E, 17F, and 17G provide the maximum transconductance for OECTs fabricated from ambient-CF, degassed-CF:B(C₆F₅)₃(100 mol %), and degassed-CF:C₆₀F₄₈ (100 mol %) respectively. Average transconductance values from a set of 6 OECTs are indicated below the graphs. FIG. 17H provides a box-and whisker plot, showing the median center line, upper and lower quartile box limits, whiskers and outlier for the C₆₀F₄₈ p-doped OECTs. Threshold voltage statistics were taken for 6 OECTs per system, and demonstrate a characteristic shift towards 0 V for the doped systems. All OECTs were measured at V_{D}=−0.6 V and tested in air in a top-gate bottom-contact transistor architecture with a silver/silver chloride pellet as the gate electrode, and 0.1 mol/L NaCl_{aq}. as the electrolyte. All OECTs in FIG. 17 had channel lengths and widths of 50 μm and 500 m, respectively.

FIG. 17D through 17H show that gₘ increases in pgBTTT OECTs processed from degassed-CF and p-doped with either C₆₀F₄₈ or B(C₆F₅)₃, when compared to OECTs processed from ambient-CF, and V_{T} shifts towards 0 V, consistent with successful p-doping. I_{OFF} also increases in pgBTTT OECTs processed from degassed-CF:C₆₀F₄₈(100 mol %) OECTs.

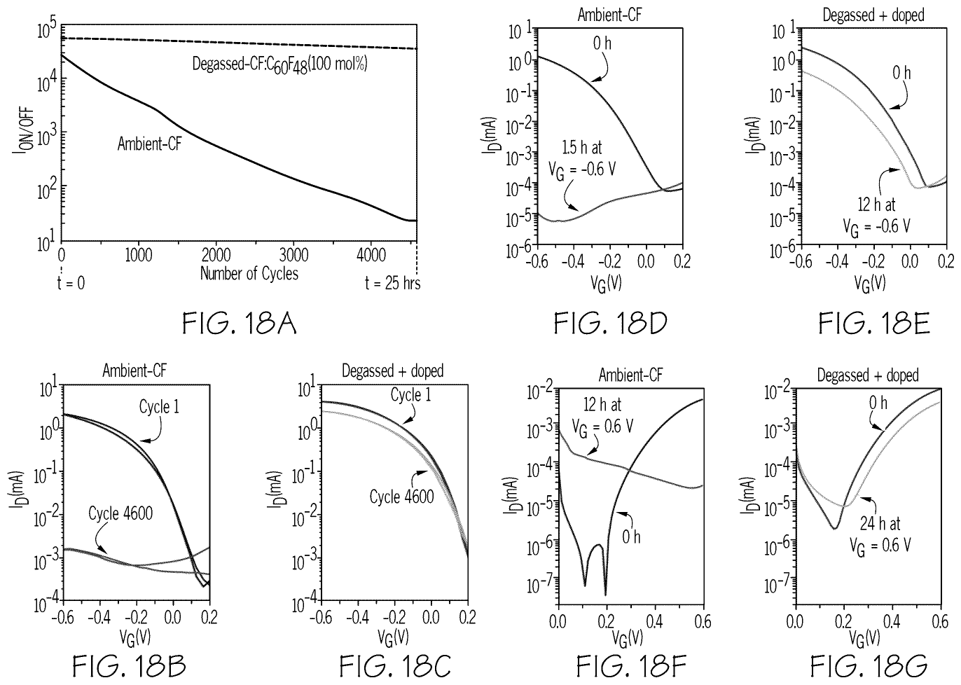

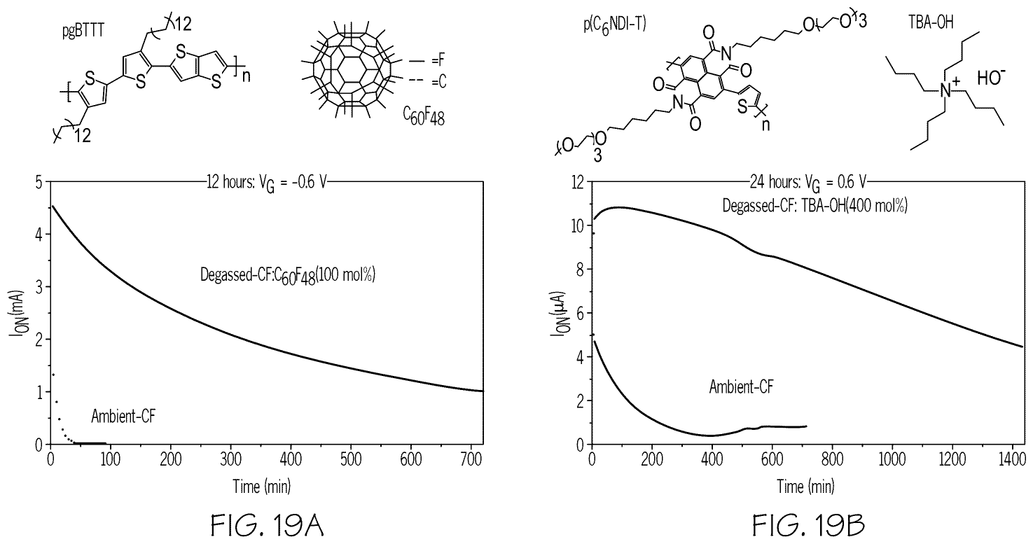

With reference to FIGS. 18D and 18E, the impact on pgBTTT stability in air using 0.1 mol/L NaCl_{aq}. electrolyte, where pgBTTT OECTs processed from ambient-CF and degassed-CF:C₆₀F₄₈(100 mol %) were subjected to much harsher biasing conditions, namely V_{G}=−0.6 V applied constantly for 12 h, with a transfer curve measured quickly every 5 minutes to monitor the impact from biasing was accessed. FIG. 18A provides 25-hour stability tests comparing on-off ratio (I_{ON/OFF}) degradation as a function of time, in p(g3T2) OECTs processed from ambient-CF and degassed-CF:C₆₀F₄₈(100 mol %). FIGS. 18B, and 18C provide the first and last cycles of the stability testing in FIG. 18A. FIGS. 18D and 18E as well as FIG. 19A show that ambient-CF OECTs were not functional after 1.5 h. Comparatively, pgBTTT OECTs processed from degassed-CF:C₆₀F₄₈(100 mol %) were still functional after 12 h.

With reference to FIGS. 18F and 18G, the impact of degassing and doping on stability in n-type OECTs: p(C₆NDI-T)⁸⁵ n-doped with TBA-OH was accessed. V_{G}=0.6 V was applied for 24 hours with FIGS. 18F and 18G as well as 19B showing that, while ambient-CF OECTs are not functional, p(C₆NDI-T) OECTs processed from degassed-CF:TBA-OH(100 mol %) are fully operational after 24 h of a high, constant gate bias, with I_{ON} only decreasing from 9.6 μA to 4.4 μA.

The testing with ultraviolet photoelectron spectroscopy, density functional theory, and electron paramagnetic resonance demonstrated that oxygen dissolved in chloroform acts as a p-dopant in OECTs and OMIECs. While oxygen p-doping impacts OECT electronic performance, the presence of oxygen also jeopardizes OECT stability. The methods of the present disclosure simultaneously remove the risks from oxygen, while enhancing OECT stability and operating metrics. First, the solvent is degassed using a freeze-pump-thaw method. Second, the OMIEC is doped. Improvements in the μμC* product, gₘ, μ and I_{ON/OFF} are shown to arise from synergistic p-doping and structural changes, using ultraviolet photoelectron spectra, electron paramagnetic resonance, ultraviolet-visible atomic force microscopy, grazing-incidence wide-angle X-ray scattering and Fourier transform infrared spectroscopy. This strategy may also be used in accordance with the present disclosure to tune V_{T}, and works in oxygen-rich environments, in more than one solvent, with more than one polymer, and more than one dopant. The improvement in OECT stability may be explained by ‘pre-doping’, that makes p-type OMIECs more difficult to oxidize, and n-type OMIECs harder to reduce and therefore less reactive in oxygen and water. A crucial part of improving OECT stability using chemical doping is to first degases the solvent in accordance with the methods of the present disclosure.

The various experimental techniques utilized for testing are provided to fully explain the provided experimental data.

Density Functional Theory Calculations. Density functional theory (DFT) calculations were performed for p(g3T2)-based oligomers of 3.5 repeat units each (14 thiophene units) and six small molecules that may be found in chloroform (chlorine gas, hydrochloric acid, hydrogen peroxide, oxygen gas, phosgene, and trichloroacetic acid). The long-range corrected hybrid functional LC-ωHPBE, optimally tuned with respect to both the highest occupied molecular orbital (HOMO) and lowest unoccupied molecular orbital (LUMO) of the p(g3T2) oligomer, and the 6-31G(d) basis set were used. The geometry of the neutral and charged states (+1,−1) for each species were optimized, and an implicit solvation model utilizing the polarizable continuum model (PCM) was used to account for the chloroform solvent environment. The ionization energy (IE) and the electron affinity (EA) were calculated as the energy difference between the charged state and the neutral state. To assess accuracy of the results, calculations at MP2 level of theory on the DFT geometries were performed and all gas-phase results were compared to available experimental data. The DFT approach presented the smallest total mean square error for the EA and IE. All calculations were performed using the Gaussian 16 Revision A.03 quantum chemical calculation package.

Organic electrochemical transistor preparation. All OECT devices were fabricated on 2 cm×2 cm Borofloat glass slides cleaned by a three-step solvent sonication for 10 minutes for each step. First by sonicating with a 5% volume fraction Decon-90 soap and DI water solution, then acetone, and lastly by isopropanol alcohol. The sonicated substrates were then blow dried by N₂ and then cleaned by ultraviolet ozone for 10 minutes using a Samco UV-1 bench top cleaner with 0.5 L/min O₂ gas flow. The source and drain electrodes were patterned by thermally evaporating a 5 nm metal Cr adhesion layer followed by 40 nm Au conduction layer using an Angstrom physical vapor deposition system with channel dimensions of 500 μm width and 50 μm length using a custom shadow mask purchased from Angstrom After thermal evaporation, the surface of the patterned substrates were activated by ultraviolet ozone for 15 minutes to increase wettability using the same bench top cleaner with 0.5 L/min O₂ gas flow followed by adhesion promotor application using (3-(trimethoxysilyl)propyl methacrylate) purchased from Tokyo Chemical Industry Co. in an isopropanol alcohol:DI water:(3-(trimethoxysilyl)propyl methacrylate) solution at a volume ratio of 100:100:3. The substrates were immersed in the adhesion promotor solution for 30 minutes, then rinsed with isopropanol alcohol and allowed to air dry. A 2 μm layer of Parylene C was deposited on the substrates using a SCS Labcoater 2 and dichloro-p-cyclophane Parylene dimer purchased from Specialty Coating Systems. After deposition, a 4% volume fraction microsoap solution was spin coated onto the parylene coated substrates at 6000 rpm (1 rpm=2π/60 rad s⁻¹) to promote delamination of a second layer of parylene. The second 4 μm layer of Parylene C was applied using the same system to serve as a sacrificial patterning layer. Photolithography was used to pattern the Parylene C on the substrates by spin casting a 9 μm later of SPR 220-7 positive photoresist, exposing the substrates using a custom photomask and Suss MA6 contact aligner with a i-line UVA light source with 365 nm wave length. M-26 developer was used to develop the photoresist by soaking for 5 minutes, rinsing with DI water and blow drying with N₂. Finally, a March reactive ion etcher (RIE) system was used to etch the photolithography patterned channel and contact features by O₂ reactive ion etching with 25 sccm of O₂ gas, 40 Pa pressure chamber pressure, and 300 Watt power. A thin film of the prepared polymer solutions were coated on to the OECT substrates by statically spin coating 50 QL of polymer at 500 rpm for 10 s then 600 rpm for 30 s. All degassed solutions were spin coated in an N₂ filled glove box and ambient solutions were spin coated in air. The 1,2-dichlorobenzene OECTs were spin coated onto the OECT substrates at 500 rpm for 10 s then 600 rpm for 30 s and then annealed at 40° C. hotplate for 30 minutes before testing.

Polymer solution preparation. All ambient polymer solutions were prepared in air using solvents stored in air as received. Ambient-chloroform p(g3T2), p(g2T2-g4T2), and pgBTTT solutions were prepared in solvent blend with a volume ratio of 20% volume fraction chlorobenzene to 80% volume fraction chloroform at a 5 mg/mL concentration. Ambient-1,2-dichlorobenzene p(g3T2) polymer solution was prepared in a solvent blend with a volume ratio of 20% volume fraction chlorobenzene to 80% volume fraction 1,2-dichlorobenzene at a 5 mg/mL concentration. Non-anhydrous, amylene stabilized chloroform was used and purchased from Electron Microscopy Sciences. Anhydrous chlorobenzene was purchased from J.T.Baker and 1,2-dichlorobenzene used was purchased from Sigma-Aldrich. All solvents were filtered with a PTFE membrane syringe filter of 0.45 □m pore size. The same solvents were then degassed using the freeze-pump-thaw method, sealed, and stored in an N₂ filled glove box. Degassed-chloroform p(g3T2), p(g2T2-g4T2), and pgBTTT solutions were prepared in an N₂ filled glove box with the same solvent ratios as before using degassed solvents. Degassed 1,2-dichlorobenzene p(g3T2) polymer solution was prepared using the same solvent ratios as before with degassed solvents in an N₂ filled glove box. Degassed C₆₀F₄₈ and BCF dopant solutions were prepared using the same degassed chlorobenzene in an N₂ filled glove box at varying concentrations. The degassed C₆₀F₄₈ dopant solution was admixed with a 5 mg/mL solution of p(g3T2) and p(g2t2-g4T2) consisting of the same degassed chloroform to form a p(g3T2):C₆₀F₄s solution containing 80% chloroform and 20% volume fraction chlorobenzene. The p(g3T2):C₆₀F₄s doped solutions were prepared in (0, 50, 100, 300, and 600) mol % concentrations using the same methods as previously reported so that effects from solvent interactions are normalized for every solution. p(g2T2-g4T2):C₆₀F₄₈ doped solutions were prepared on (0, 20, 50, and 100) mol % concentrations. In each case, the mol % of the chemical dopants, i.e. C₆₀F₄₈, B(C₆F₅)₃ and TBA-OH, were calculated as a percentage of the total molar mass of their respective polymers, which were each in 5 mg/ml solutions. A degassed p(g3T2):C₆₀F₄s doped solution was prepared with solvent ratio containing 80% volume fraction 1,2-dichlorobenzene and 20% volume fraction C₆₀F₄₈ chlorobenzene solution in an N₂ filled glove box. A degassed pgBTTT:BCF solution was prepared in an N₂ filled glove box with degassed chloroform and 20% volume fraction chlorobenzene BCF dopant solution. Each solution was allowed to rest overnight before spin coating. All solutions were prepared on the same day from the same polymer batch for each polymer:dopant sample set.

Organic electrochemical transistor characterization and analysis. Unless otherwise indicated all devices were tested in an inert environment, by using an N₂ filled glove box and [BMIM]BF₄ as an ionic liquid electrolyte. This was to remove any impact from oxygen. A bottom-gate bottom-contact transistor architecture was used for the [BMIM]BF₄ electrolyte, that used a 500×500 Dm gold patterned electrode coated with p(g3T2) as the gate. All current-voltage characteristics were measured using a Keysight B2912A Precision Source/Measure Unit. The scan rate for all the transfer data is 0.52 V/s with V_{G}=0.2V to −0.8V and V_{D}:−0.05V, −0.6V. The scan rate for the output curves is 0.28 V/s with V_{D}=0 V to −0.6 V and V_{G}=0 V to V_{G}=−0.8 V, with a step of ΔV_{G}=0.12 V. All comparative transfer and output currents were normalized according to film thicknesses to account for the effects of film thickness. OECTs tested in non-inert environments were tested outside the glovebox and used an aqueous electrolyte, 0.1 mol/L NaCl_{aq}, in a top-gate bottom-contact architecture, that used a Ag/AgCl pellet as the gate electrode. All OECTs were prepared on the same day for each polymer:dopant sample set. Stability tests were carried out in the ambient testing setup, and used a wax-sealed polydimethylsiloxane (PDMS) well to prevent the 0.1M NaCl aqueous electrolyte from evaporating during the test windows.

Electrochemical Impedance Spectroscopy and Capacitance Voltage. Cyclic voltammetry was taken using an Autolab potentiostat in air at a rate of 0.05 V/s for 3 cycles. Electrochemical impedance spectroscopy (EIS) was used to determine the volumetric capacitance for all devices where [BMIM]BF₄ ionic liquid was used as the electrolyte solution, a platinum (Pt) wire served as the counter electrode, and two 500×500 μm gold (Au) patterned electrodes coated with p(g3T2) were used as the working and reference electrodes. Afterwards, CV and EIS scans were taken again using aqueous 0.1 mol/L NaCl electrolyte and Pt wire as the counter electrode. The same 500×500 μm Au electrode coated with p(g3T2) was used as the working electrode and an Ag/AgCl pellet was used as the reference electrode. EIS measurements were taken at 10 mV sine wave at frequencies ranging from 1×10⁵ Hz to 0.1 Hz and a DC offset potential at the max V_{Gm} for the polymer thin film. The data analysis was done using Metrohm Autolab NOVA software. We note that the EIS set ups are different for the two electrolytes, i.e., [BMIM]BF₄ and NaCl_{aq}. The set ups use different counter electrode materials (AgAgC1 and polymer coated Au, for the NaCl_{aq}. and BMIM]BF₄, respectively), and position of the counter electrode in the EIS set up is different. The position is different because of the different OECT architectures: bottom-contact top-gate for the NaCl_{aq}. and bottom-contact bottom-gate for the [BMIM]BF₄.

Thickness measurements. A Dektak Profilometer was used to measure film thickness of the polymer thin-films as cast in the OECT channels and on the gate electrode. Thickness value was determined by taking the average from five thickness measurements.

Ultraviolet photoelectron spectroscopy. A thin film of p(g3T2) processed from degassed-CF and a thin-film p(g3T2):C₆₀F₄₈ were formed by spin coating 5 mg/mL polymer in an N₂ environment on clean ITO substrates at 1800 rpm for 30 s. Another p(g3T2) thin film was prepared in the same way using ambient solvents and spin cast in air. UPS measurements were performed using a PHI 5600 UHV system coupled with a hemispherical electron energy analyser and a multichannel detector with a 5.85 eV pass energy. An Excitech H Lyman-α lamp (E-lux 121, 10.2 eV emission) was used as the photon source with a 90° mirror (E-lux EEM Optical Module) and a dry oxygen purge through the beam path at between 933 Pa and 1333 10 Pa. A negative 5 V bias was applied to the samples during the measurements. The work function (WF) is determined by the difference between the intersection of the linear fit to the secondary electron cut-off SECO edge with the background and the photon energy (hv) of the UV source. hv=10.2 eV, and therefore WF=10.2−SECO.

Electron Paramagnetic Resonance. EPR polymer solution samples were prepared at a concentration of 10 mg/mL of p(g3T2) polymer with a solvent solution containing 80% volume fraction degassed chloroform and 20% volume fraction degassed chlorobenzene in an N₂ filled glove box. A capillary tube was filled with the degassed solution and sealed airtight in an N₂ filled glove box before testing. An ambient p(g3T2) polymer solution was prepared using ambient chloroform and chlorobenzene in the same solvent ratios in air. A capillary tube was filled with the ambient p(g3T2) solution and sealed in air before testing. Both capillaries were filled with identical volume. Another set of chloroform p(g3T2) solutions were prepared at a concentration of 5 mg/mL containing 80% volume fraction chloroform and 20% volume fraction chlorobenzene with ambient solvents and doped p(g3T2):C₆₀F₄₈ (100 mol %) solution was prepared in the same way but using 20% volume fraction of a C₆₀F₄₈ degassed chlorobenzene solution. A third capillary tube was filled with the same C₆₀F₄₈ solution used to dope the 100 mol % p(g3T2):C₆₀F₄₈ solution. The EPR spectra was recorded using a Bruker EMX PremiumX at room temperature, with 15 dB microwave attenuation, 100 kHz modulation frequency, and a modulation amplitude of 1.00 G. EPR measurements were carried out at room temperature, with identical sample volume and measurement conditions.

Atomic force microscopy. Topographical information and surface roughness measurements were taken using a Cypher S atomic force microscope operating in tapping mode. Data analysis was carried out using Igor Pro.

Grazing Incidence Wide Angle X-ray. Films of each polymer we prepared as described above on silicon oxide coated silicon substrates. The GIWAXS data was collected at the 11-BM CMS beamline of NSLS-II in a vacuum environment using a Pilatus 900 k detector and a photon energy of 13.5 keV. The sample detector distance was nominally 260 m, and the angle of incidence was varied between 0.1 and 0.14 degrees relative to the substrate. Analysis was performed using the Nika software package for wavemetrics Igor Pro.

Fourier Transform Infrared Spectroscopy. Theoretical IR vibrational spectra were calculated using frequency calculations on optimized structures at B3LYP/6-31G* level in the gas phase, using a scaling factor of 0.96 based on data from NIST (https://cccbdb.nist.gov/vibscalejust.asp). Spectra were produced using GaussSum software with line broadening of full width at half maximum (FWHM) 10 cm⁻¹. Vibrational modes were visualized with the Jmol software.

Ultraviolet photoelectron spectroscopy on 5,11-bis(triethylsilylethynyl)anthradithiophene (TES-ADT). Experiments demonstrating oxygen is present in the ambient-CF, but not present in the degassed-CF. We prepared two chloroform solutions with TES-ADT of the same concentration. One solution was prepared in a N₂ filled glove box using degassed chloroform and sealed in an airtight UV-transparent cuvette and the other solution was prepared in air using ambient chloroform and sealed in another UV-transparent cuvette. The initial UV spectra of the degassed-TES-ADT and ambient-TES-ADT solutions were first matched to ensure identical initial concentration. The cuvettes were then subject to incandescent light for 1-minute increments. UV spectra were acquired after every minute of light exposure. Both cuvettes were placed at equal distance from the light source. A dual fiber optic illuminator was used to ensure even light irradiation to the samples. UV spectra was acquired using an Agilent Cary 60 UV-Vis spectrophotometer from 300 nm to 700 nm. A background spectrum acquired from a cuvette with ambient chloroform was recorded for baseline correction.

Having described various embodiments, it should be understood that the various aspects of the method of preparing a polymer solution for organic electrochemical transistor preparation and the polymer solution for organic electrochemical transistor preparation proper may be utilized in conjunction with various other aspects.

In a first aspect, the disclosure provides a method of preparing a polymer solution for organic electrochemical transistor preparation, the method comprising preparing a solvent solution; preparing a dopant solution; and combining the solvent solution and the dopant solution at 60 to 90 volume percent solvent solution and 10 to 40 volume percent dopant solution, wherein preparing the solvent solution comprises degassing a first solvent to form a degassed first solvent and combining the degassed first solvent with a polymer; and preparing the dopant solution comprises degassing a second solvent to form a degassed second solvent and combining the degassed second solvent with a p-dopant.

In a second aspect, the disclosure provides the method of the first aspect, in which the solvent solution and the dopant solution are combined at 70 to 90 volume percent solvent solution and 10 to 30 volume percent dopant solution.

In a third aspect, the disclosure provides the method of the first aspect, in which the solvent solution and the dopant solution are combined at 75 to 85 volume percent solvent solution and 15 to 25 volume percent dopant solution.

In a fourth aspect, the disclosure provides the method of any of the first through third aspects, in which the first solvent is chloroform or 1,2-dichlorobenzene.

In a fifth aspect, the disclosure provides the method of any of the first through fourth aspects, in which the polymer comprises a glycolated polythiophene.

In a sixth aspect, the disclosure provides the method of the fifth aspects, in which the polymer is p(g3T2), p(g2T2-g4T2), pgBTTT, or a combination thereof.

In a seventh aspect, the disclosure provides the method of the sixth aspect, in which the first solvent is chloroform.

In an eighth aspect, the disclosure provides the method of any of the first through third aspects, in which the polymer is p(g3T2) and the first solvent is 1,2-dichlorobenzene.

In a ninth aspect, the disclosure provides the method of any of the first through eighth aspects, in which the second solvent is chlorobenzene.

In a tenth aspect, the disclosure provides the method of any of the first through ninth aspects, in which the p-dopant comprises fluorinated fullerene (C₆₀F₄₈), tris(pentafluorophenyl)borane (B(C₆F₅)₃), tributyl ammonium hydroxide (TBA-OH), or a combination thereof.

In an eleventh aspect, the disclosure provides the method of any of the first through fourth aspects, in which the polymer is p(g3T2) and the p-dopant is C₆₀F₄₈.

In a twelfth aspect, the disclosure provides the method of any of the first through fourth aspects, in which the polymer is p(g2T2-g4T2) and the p-dopant is C₆₀F₄₈.

In a thirteenth aspect, the disclosure provides the method of any of the first through fourth aspects, in which the polymer is pgBTTT and the p-dopant is B(C₆F₅)₃.

In a fourteenth aspect, the disclosure provides the method of the eleventh aspect, in which the C₆₀F₄₈ is provided at a 0.5:1 to 6:1 molar ratio relative to the p(g3T2).

In a fifteenth aspect, the disclosure provides the method of the twelfth aspect, in which the C₆₀F₄₈ is provided at a 0.2:1 to 1:1 molar ratio relative to the p(g2T2-g4T2).

In a sixteenth aspect, the disclosure provides the method of any of the first through sixth fifteenth, in which the solvent solution comprises 2 to 10 mg/ml of the polymer.

In a seventeenth aspect, the disclosure provides the method of any of the first through sixth fifteenth, in which the solvent solution comprises 3 to 7 mg/ml of the polymer.

In an eighteenth aspect, the disclosure provides a polymer solution for organic electrochemical transistor preparation comprising a solvent solution comprising a degassed first solvent and a polymer; and a dopant solution comprising a degassed second solvent and a p-dopant. The solvent solution and the dopant solution are combined at 60 to 90 volume percent solvent solution and 10 to 40 volume percent dopant solution.

In a nineteenth aspect, the disclosure provides the polymer solution of the eighteenth aspect in which the first solvent is chloroform or 1,2-dischlorobenzene; the second solvent is chlorobenzene; and the polymer comprises a glycolated polythiophene.

In a twentieth aspect, the disclosure provides the polymer solution of the eighteenth or nineteenth aspect in which the p-dopant comprises fluorinated fullerene (C₆₀F₄₈), tris(pentafluorophenyl)borane (B(C₆F₅)₃), tributyl ammonium hydroxide (TBA-OH), or a combination thereof.

It should be apparent to those skilled in the art that various modifications and variations may be made to the embodiments described within without departing from the spirit and scope of the claimed subject matter. Thus, it is intended that the specification cover the modifications and variations of the various embodiments described within provided such modification and variations come within the scope of the appended claims and their equivalents.

As used throughout, the singular forms “a,” “an” and “the” include plural referents unless the context clearly dictates otherwise. Thus, for example, reference to “a” component includes aspects having two or more such components, unless the context clearly indicates otherwise.

It should be understood that any two quantitative values assigned to a property or measurement may constitute a range of that property or measurement, and all combinations of ranges formed from all stated quantitative values of a given property or measurement are contemplated in this disclosure.

Unless otherwise defined, all terms (including technical and scientific terms) used herein have the same meaning as commonly understood by one of ordinary skill in the art to which this disclosure belongs. It will be further understood that terms such as those defined in commonly used dictionaries, should be interpreted as having a meaning that is consistent with their meaning in the context of the relevant art and the present disclosure, and will not be interpreted in an idealized or overly formal sense unless expressly so defined herein.

As used here and in the appended claims, the words “comprise,” “has,” and “include” and all grammatical variations thereof are each intended to have an open, non-limiting meaning that does not exclude additional elements or steps.

Having described the subject matter of the present disclosure in detail and by reference to specific embodiments thereof, it is noted that the various details disclosed within should not be taken to imply that these details relate to elements that are essential components of the various embodiments described within, even in cases where a particular aspect is illustrated in each of the drawings that accompany the present description. Further, it should be apparent that modifications and variations are possible without departing from the scope of the present disclosure, including, but not limited to, embodiments defined in the appended claims. More specifically, although some aspects of the present disclosure are identified as particularly advantageous, it is contemplated that the present disclosure is not necessarily limited to these aspects.

What is claimed is:

1. A method of preparing a polymer solution for organic electrochemical transistor preparation comprising:
preparing a solvent solution;
preparing a dopant solution; and
combining the solvent solution and the dopant solution at 60 to 90 volume percent solvent solution and 10 to 40 volume percent dopant solution,
wherein:
preparing the solvent solution comprises degassing a first solvent to form a degassed first solvent and combining the degassed first solvent with a polymer; and
preparing the dopant solution comprises degassing a second solvent to form a degassed second solvent and combining the degassed second solvent with a p-dopant.

2. The method of claim 1, wherein the solvent solution and the dopant solution are combined at 70 to 90 volume percent solvent solution and 10 to 30 volume percent dopant solution.

3. The method of claim 1, wherein the solvent solution and the dopant solution are combined at 75 to 85 volume percent solvent solution and 15 to 25 volume percent dopant solution.

4. The method of claim 1, wherein the first solvent is chloroform or 1,2-dichlorobenzene.

5. The method of claim 1, wherein the polymer comprises a glycolated polythiophene.

6. The method of claim 5, wherein the polymer is p(g3T2), p(g2T2-g4T2), pgBTTT, or a combination thereof.

7. The method of claim 6, wherein the first solvent is chloroform.

8. The method of claim 1, wherein the polymer is p(g3T2) and the first solvent is 1,2-dichlorobenzene.

9. The method of claim 1, wherein the second solvent is chlorobenzene.

10. The method of claim 1, wherein the p-dopant comprises fluorinated fullerene (C₆₀F₄₈), tris(pentafluorophenyl)borane (B(C₆F₅)₃), tributyl ammonium hydroxide (TBA-OH), or a combination thereof.

11. The method of claim 1, wherein the polymer is p(g3T2) and the p-dopant is C₆₀F₄₈.

12. The method of claim 1, wherein the polymer is p(g2T2-g4T2) and the p-dopant is C₆₀F₄₈.

13. The method of claim 1, wherein the polymer is pgBTTT and the p-dopant is B(C₆F₅)₃.

14. The method of claim 11, wherein the C₆₀F₄₈ is provided at a 0.5:1 to 6:1 molar ratio relative to the p(g3T2).

15. The method of claim 12, wherein the C₆₀F₄₈ is provided at a 0.2:1 to 1:1 molar ratio relative to the p(g2T2-g4T2).

16. The method of claim 1, wherein the solvent solution comprises 2 to 10 mg/ml of the polymer.

17. The method of claim 1, wherein the solvent solution comprises 3 to 7 mg/ml of the polymer.

18. A polymer solution for organic electrochemical transistor preparation comprising:
a solvent solution comprising a degassed first solvent and a polymer; and
a dopant solution comprising a degassed second solvent and a p-dopant;
wherein:
the solvent solution and the dopant solution are combined at 60 to 90 volume percent solvent solution and 10 to 40 volume percent dopant solution.

19. The polymer solution of claim 18, wherein:
the first solvent is chloroform or 1,2-dischlorobenzene;
the second solvent is chlorobenzene; and
the polymer comprises a glycolated polythiophene.

20. The polymer solution of claim 18, wherein the p-dopant comprises fluorinated fullerene (C₆₀F₄₈), tris(pentafluorophenyl)borane (B(C₆F₅)₃), tributyl ammonium hydroxide (TBA-OH), or a combination thereof.
